(19) United States
(12) Patent Application Publication
(10) Pub. No.: US 2017/0098561 A1
(43) Pub. Date: Apr. 6, 2017

(54) METHOD OF MANUFACTURING SEMICONDUCTOR DEVICE

(71) Applicant: HITACHI KOKUSAI ELECTRIC INC., Tokyo (JP)

(72) Inventors: Naofumi OHASHI, Toyama-shi (JP); Satoshi TAKANO, Toyama-shi (JP); Toshiyuki KIKUCHI, Toyama-shi (JP)

(73) Assignee: HITACHI KOKUSAI ELECTRIC INC., Tokyo (JP)

(21) Appl. No.: 15/383,903

(22) Filed: Dec. 19, 2016

Related U.S. Application Data
(62) Division of application No. 14/858,385, filed on Sep. 18, 2015.

(30) Foreign Application Priority Data
Mar. 31, 2015 (JP) 2015-071084

(51) Int. Cl. H01L 21/67; C23C 16/52; H01L 21/3105; H01L 29/66; H01L 21/28

(52) U.S. Cl. CPC H01L 21/67098; H01L 21/67248; H01L 21/67253; H01L 29/66795; H01L 21/28158; H01L 29/66545; H01L 21/28026; H01L 21/31053; C23C 16/52

(57) ABSTRACT

A substrate processing apparatus includes a reception part configured to receive film thickness distribution data of a substrate on which a channel region, an insulating film on the channel region, and a first silicon-containing layer as a portion of a silicon-containing film on the insulating film are formed; a substrate mounting part configured to mount the substrate; and a gas supply part configured to supply a gas to form a second silicon-containing layer as a portion of the silicon-containing film on the first silicon-containing layer to have a film thickness distribution different from a film thickness distribution of the film thickness distribution data, thereby correcting a film thickness of the silicon-containing film.

### CROSS-REFERENCE TO RELATED APPLICATION

This application is a divisional of U.S. patent application Ser. No. 14/858,385 filed Sep. 18, 2015, based upon and claims the benefit of priority from Japanese Patent Application No. 2015-071084, filed Mar. 31, 2015, the entire contents of which are incorporated herein by reference.

### TECHNICAL FIELD

The present disclosure relates to a substrate processing apparatus and a substrate processing system.

### BACKGROUND

Recently, semiconductor devices tend to be highly integrated. In line with the tendency of high integration of semiconductor devices, pattern sizes have been remarkably miniaturized. The patterns are formed through a hard mask or resist forming process, a lithography process, an etching process and the like. When forming the patterns, variations in the characteristics of the semiconductor devices should be prevented.

However, a variation in a width of a circuit to be formed may occur due to processing problems. In particular, such variation may significantly affect the characteristics of semiconductor devices with miniaturized patterns.

### SUMMARY

The present disclosure provides some embodiments capable of suppressing variation in a characteristic of a semiconductor device.

According to one embodiment of the present disclosure, there is provided a substrate processing apparatus, including: a reception part configured to receive film thickness distribution data of a substrate on which a channel region, an insulating film on the channel region, and a first silicon-containing layer as a portion of a silicon-containing film on the insulating film are formed; a substrate mounting part configured to mount the substrate; and a gas supply part configured to supply a gas to form a second silicon-containing layer as a portion of the silicon-containing film on the first silicon-containing layer to have a film thickness distribution different from a film thickness distribution of the film thickness distribution data, thereby correcting a film thickness of the silicon-containing film.

### BRIEF DESCRIPTION OF THE DRAWINGS

FIG. 1 is a flowchart of manufacturing a semiconductor device according to an embodiment of the present disclosure.

FIGS. 2A and 2B are explanatory views of a wafer according to an embodiment.

FIGS. 3A to 3C are explanatory views illustrating a portion of a manufacturing flow of a semiconductor device according to an embodiment.

FIG. 4 is an explanatory view illustrating a polishing apparatus according to an embodiment.

FIG. 5 is an explanatory view illustrating a polishing apparatus according to an embodiment.

FIG. 6 is an explanatory diagram illustrating a distribution of a film thickness of a polysilicon (poly-Si) layer according to an embodiment.

FIGS. 7A and 7B are explanatory views illustrating a process state of a wafer according to an embodiment.

FIG. 8 is an explanatory diagram illustrating a distribution of a film thickness of a polysilicon layer according to an embodiment.

FIGS. 9A and 9B are explanatory views illustrating a process state of a wafer according to an embodiment.

FIG. 10 is an explanatory diagram illustrating a distribution of a film thickness of a polysilicon layer according to an embodiment.

FIG. 11 is an explanatory view illustrating a substrate processing apparatus according to an embodiment.

FIG. 12 is an explanatory view illustrating a shower head of the substrate processing apparatus according to an embodiment.

FIG. 13 is a block diagram illustrating a schematic configuration of a controller according to an embodiment.

FIGS. 14A and 14B are explanatory views illustrating a process state of a wafer according to an embodiment.

FIGS. 15A and 15B are explanatory views illustrating a process state of a wafer according to an embodiment of the present disclosure.

FIGS. 16A and 16B are explanatory views illustrating a process state of a wafer according to an embodiment.

FIGS. 17A and 17B are explanatory views illustrating a process state of a wafer regarding a comparative example.

FIGS. 18A and 18B are explanatory views illustrating a process state of a wafer regarding a comparative example.

FIG. 19 is an explanatory view illustrating a system according to an embodiment of the present disclosure.

### DETAILED DESCRIPTION

Hereinafter, embodiments of the present disclosure will be described.

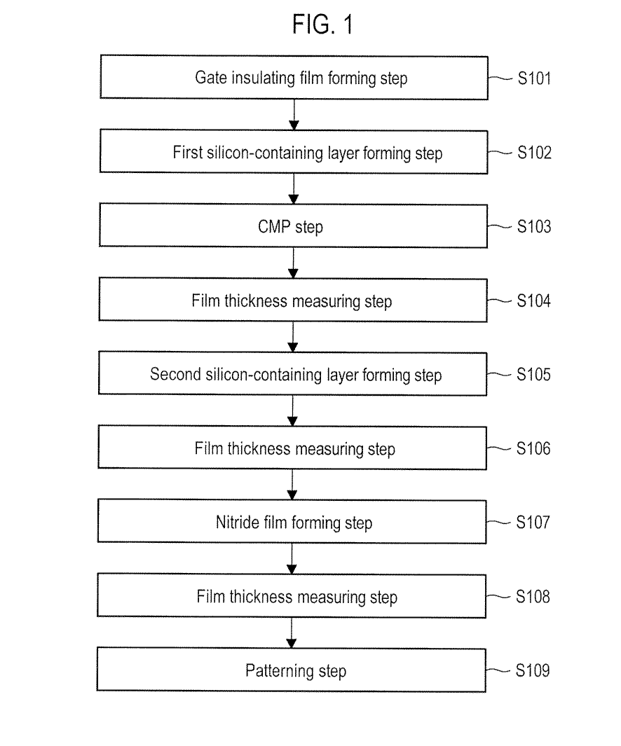

First, one of processes of manufacturing a semiconductor device will be described using FinFET as an example, which is one of semiconductor devices, with reference to FIGS. 1 to 3.

### (Gate Insulating Film Forming Step S101)

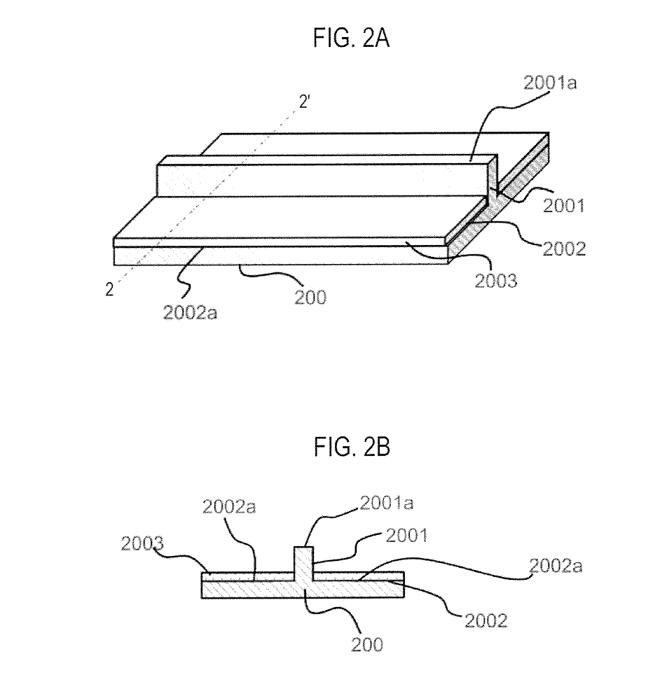

In a gate insulating film forming step S101, for example, a wafer 200 illustrated in FIGS. 2A and 2B is loaded to a gate insulating film forming apparatus. FIG. 2A is a perspective view illustrating the wafer 200, and FIG. 2B is a cross-sectional view taken along line 2-2′ of FIG. 2A. The wafer 200 is formed of silicon or the like, and has a convex structure 2001 as a channel formed in a portion thereof. The convex structure 2001 may be formed at predetermined intervals a plurality of times. The convex structure 2001 is formed by etching a portion of the wafer 200.

For the convenience of description, a portion of the wafer 200 in which a convex structure is not formed will be referred to as a concave structure 2002. That is, the wafer 200 includes at least the convex structure 2001 and the concave structure 2002. Also, in this embodiment, for the convenience of description, an upper surface of the convex structure 2001 will be referred to as a convex structure surface 2001a and an upper surface of the concave structure will be referred to as a concave structure surface 2002a.

A device isolation film 2003 is formed on the concave structure surface 2002a between adjacent convex structures to electrically insulate the convex structures. The device isolation film 2003 is formed of, for example, a silicon oxide film.

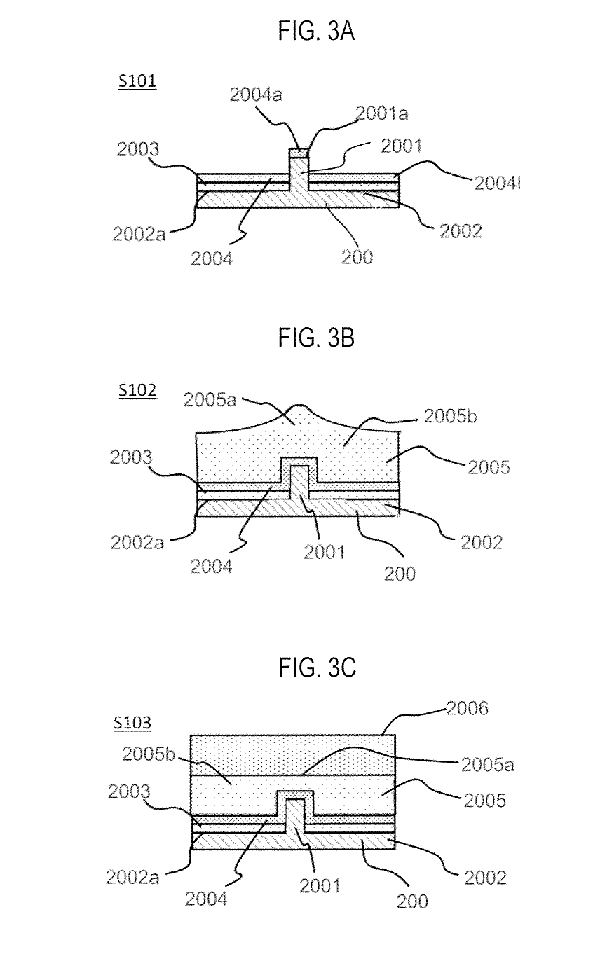

A gate insulating film forming apparatus is a known single-wafer type apparatus capable of forming a thin film, and thus, a description thereof will be omitted. In the gate insulating film forming apparatus, a gate insulating film 2004 formed of a dielectric such as, e.g., a silicon oxide film (SiO₂ film) is formed, as illustrated in FIG. 3A. When forming the gate insulating film 2004, a silicon-containing gas (for example, a hexachlorodisilane (HCDS) gas) and an oxygen-containing gas (for example, an O₃ gas) are supplied to the gate insulating film forming apparatus and react with each other to thereby form the gate insulating film 2004. The gate insulating film 2004 is formed on each of the convex structure surface 2001a and the concave structure surface 2002a. After the gate insulating film is formed, the wafer 200 is unloaded from the gate insulating film forming apparatus.

### (First Silicon-Containing Layer Forming Step S102)

Subsequently, a first silicon-containing layer forming step S102 will be described.

After the wafer 200 is unloaded from the gate insulating film forming apparatus, the wafer 200 is loaded to a first silicon-containing layer forming apparatus. As the first silicon-containing layer forming apparatus, a general single-wafer type CVD apparatus is used, and thus, a description thereof will be omitted. In the first silicon-containing layer forming apparatus, a first silicon-containing layer 2005 (also referred to as a first polysilicon layer 2005 or simply a polysilicon layer 2005) formed of polysilicon is formed on the gate insulating film 2004, as illustrated in FIG. 3B. When forming this polysilicon layer, a disilane (Si₂H₆) gas is supplied to the first silicon-containing layer forming apparatus and then thermally decomposed to thereby form the polysilicon layer. The polysilicon layer is used as a gate electrode or a dummy gate electrode. After the polysilicon layer 2005 is formed, the wafer 200 is unloaded from the first silicon-containing layer forming apparatus. Also, a film deposited on the convex structure surface 2001a is called a polysilicon layer 2005a, and a film formed on the concave structure surface 2002a is called a polysilicon layer 2005b.

### (Chemical Mechanical Polishing (CMP) Step S103)

Subsequently, a CMP step S103 will be described.

The wafer 200 unloaded from the first silicon-containing layer forming apparatus is loaded to a polishing apparatus 400.

Here, the polysilicon layer formed in the first silicon-containing layer forming step S102 will be described. As illustrated in FIG. 3B, since the wafer 200 has the convex structure 2001 and the concave structure 2002, the heights of the polysilicon layers are different from each other. Specifically, a height from the concave structure surface 2002a to a surface of the polysilicon layer 2005a on the convex structure 2001 becomes higher than a height from the concave structure surface 2002a to a surface of the polysilicon layer 2005b on the concave structure surface 2002a.

However, due to any one of or both of an exposure process and an etching process described later, the heights of the polysilicon layers 2005a and 2005b are required to be aligned. Thus, the polysilicon layer 2005 is polished to align the heights as in this step.

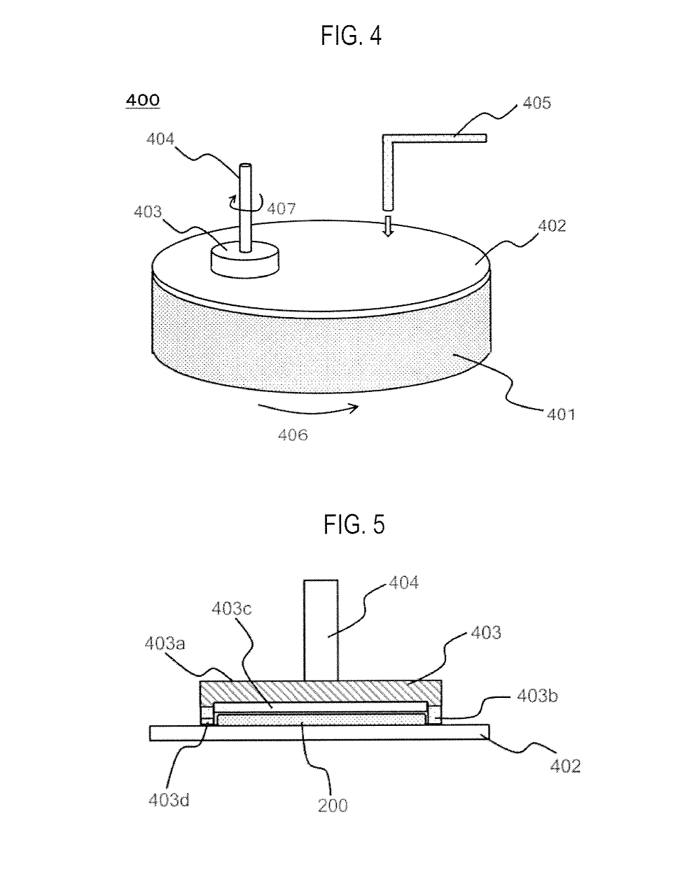

Hereinafter, details of the CMP step will be described. After the wafer 200 is unloaded from the first silicon-containing layer forming apparatus, the wafer 200 is loaded to the polishing apparatus 400 illustrated in FIG. 4.

In FIG. 4, reference numeral 401 denotes a polishing disc and reference numeral 402 denotes an abrasive cloth to polish the wafer 200. The polishing disc 401 is connected to a rotation mechanism (not shown), and when polishing the wafer 200, the polishing disc 401 rotates in a direction of an arrow 406.

Reference numeral 403 is a polishing head, and a shaft 404 is connected to an upper surface of the polishing head 403. The shaft 404 is connected to a rotation mechanism and a lifting driving mechanism (not shown). While the wafer 200 is being polished, the wafer 200 rotates in a direction of the arrow 407.

Reference numeral 405 is a supply pipe configured to supply a slurry (an abrasive). While the wafer 200 is being polished, the slurry is supplied from the supply pipe 405 to the abrasive cloth 402.

Subsequently, details of the polishing head 403 and a peripheral structure thereof will be described with reference to FIG. 5. FIG. 5 is a cross-sectional view illustrating the polishing head 403 and a peripheral structure thereof. The polishing head 403 includes a top ring 403a, a retainer ring 403b and an elastic mat 403c. While the wafer 200 is polished, an outer side of the wafer 200 is surrounded by the retainer ring 403b and the wafer 200 is pushed against the abrasive cloth 402 by the elastic mat 403c. A groove 403d is formed in the retainer ring 403b to allow the slurry to pass through from an outer side of the retainer ring to an inner side thereof. A plurality of grooves 403d is formed in a circumferential shape along the shape of the retainer ring 403b. It is configured such that fresh slurry which has not been used and slurry which has been used are replaced through the groove 403d.

Subsequently, an operation in this step will be described. When the wafer 200 is loaded into the polishing head 403, the slurry is supplied from the supply pipe 405 and the polishing disc 401 and the polishing head 403 are rotated. The slurry flows into the retainer ring 403b to polish a surface of the wafer 200. Through such polishing, as illustrated in FIG. 3C, the heights of the polysilicon layer 2005a and the polysilicon layer 2005b are aligned. After the wafer 200 is polished for a predetermined period of time, the wafer 200 is unloaded. The heights mentioned herein refer to heights of surfaces (upper ends) of the polysilicon layer 2005a and the polysilicon layer 2005b. After the wafer 200 is polished for a predetermined period of time, the wafer 200 is unloaded from the CMP apparatus 400.

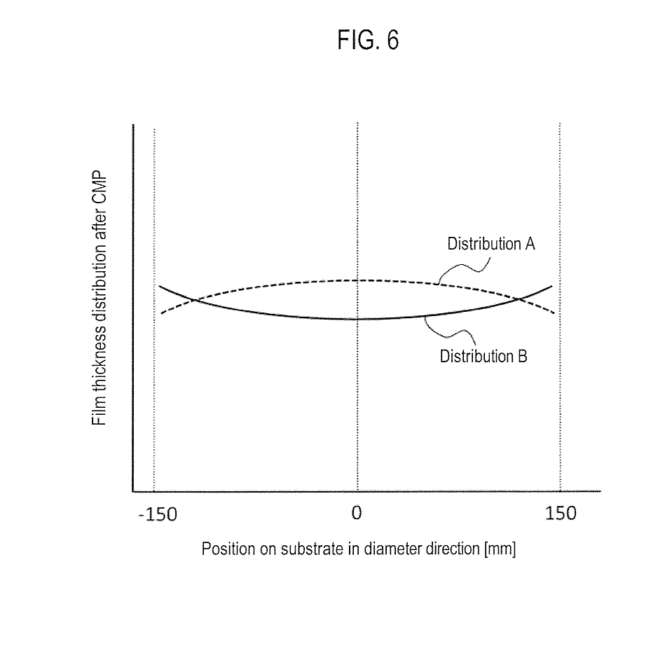

However, although the wafer 200 is polished by the CMP apparatus 400 such that the heights of the polysilicon layer 2005a and the polysilicon layer 2005b are aligned, it has been found that the heights (film thicknesses) of the polysilicon layers 2005 may not be aligned in-plane above the surface of the wafer 200, as illustrated in FIG. 6. For example, it has been found that distribution A in which a film thickness of a peripheral surface of the wafer 200 is smaller than that of a central surface thereof and distribution B in which a film thickness of a central surface of the wafer 200 is greater than that of a peripheral surface thereof occur.

When there is a bias in the film thickness distribution, variation in a width of a pattern during a lithography process or an etching process, which will be described later, may be generated. Due to this, variation in a width of a gate electrode is generated, which results in a degradation of yield.

According to the results of researches conducted by the inventors, it has been found that the problem is caused by distribution A and distribution B. The causes thereof will be described hereinafter.

The cause of distribution A arises from a supply method of slurry with respect to the wafer 200. As mentioned above, the slurry supplied to the abrasive cloth 402 is supplied from the periphery of the wafer 200 through the retainer ring 403b. Thus, slurry, which is used to polish the peripheral surface of the wafer 200, flows into the central surface of the wafer 200, while slurry, which has not been used, flows into the peripheral surface of the wafer 200. Since the slurry, which has not been used, has high polishing efficiency, the peripheral surface of the wafer 200 is polished more than that of the central surface of the wafer 200. For this reason, it has been found that a film thickness of the polysilicon layer 2005 has distribution A.

The cause of distribution B arises from abrasion of the retainer ring 403b. When a large amount of wafers 200 are polished by the polishing apparatus 400, a front end of the retainer ring 403b pushed against the abrasive cloth 402 is abraded and the groove 403d or a contact surface with the abrasive cloth 402 is deformed. For this reason, slurry to be supplied may not be supplied to an inner circumference of the retainer ring 403b. In this case, since slurry is not supplied to the peripheral surface of the wafer 200, the central surface of the wafer 200 is polished while the peripheral surface thereof is not polished. Thus, it has been found that a film thickness of the polysilicon layer 2005 has distribution B.

Accordingly, in this embodiment, as described later, a step of polishing the polysilicon layer 2005 on the wafer 200 by the polishing apparatus 400 and subsequently aligning heights of a stacked polysilicon film on the surface of the wafer 200 is performed. Here, the stacked polysilicon film refers to a stacked film in which the polysilicon layer 2005 and a polysilicon layer 2006, which will be described later, are overlapped. Also, the stacked polysilicon film may also be called a silicon-containing film.

As a specific method for aligning the heights, a film thickness distribution of the polysilicon layer 2005 is measured in a film thickness measuring step S104 after the polishing step S102, and a second polysilicon layer forming step S105 described later is executed according to the measurement data. In this manner, the variation in a width of a pattern is suppressed through an exposure process or an etching process.

### (Film Thickness Measuring Step S104)

Subsequently, a film thickness measuring step S104 will be described.

In the film thickness measuring step S104, a film thickness of the polysilicon layer 2005 after being polished is measured using a general measuring apparatus. Since a general apparatus can be used as the measuring apparatus, a detailed description thereof will be omitted. The film thickness mentioned herein refers to, for example, a height from the concave structure surface 2002a to the surface of the polysilicon layer 2005.

After the CMP step S104, the wafer 200 is loaded to the measurement apparatus. The measuring apparatus measures a film thickness (height) distribution of the polysilicon layer 2005 by measuring at least some places of the central surface and the peripheral surface of the wafer 200 that may be easily affected by the polishing apparatus 400. The measurement data are transmitted to a substrate processing apparatus 900 described later through a higher apparatus. After the measurement, the wafer 200 is unloaded.

### (Second Silicon-Containing Layer Forming Step S105)

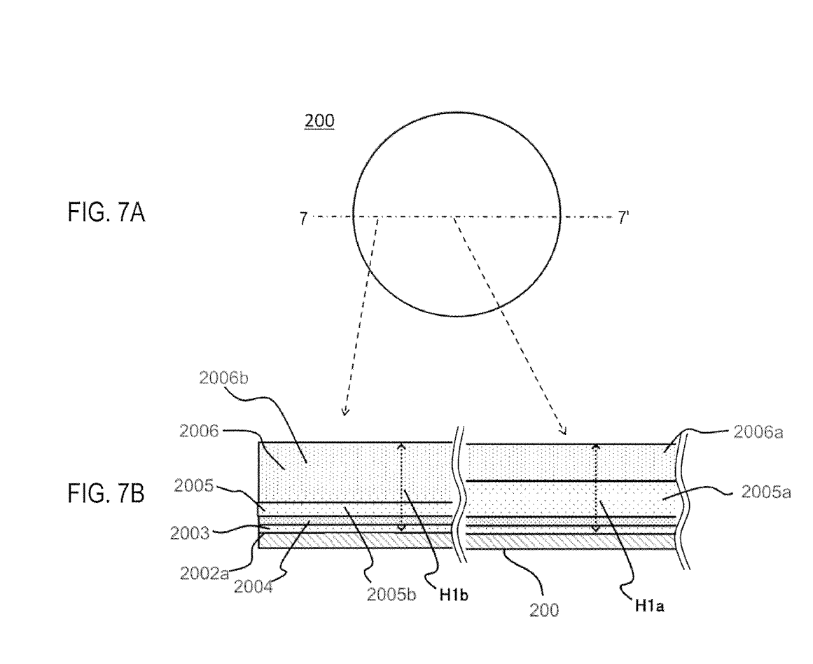

Subsequently, a second silicon-containing layer forming step will be described. The second silicon-containing layer 2006 is a polysilicon layer and has the same composition as that of the first silicon-containing layer 2005. As illustrated in FIGS. 3C and 7, the second silicon-containing layer 2006 is formed on the first silicon-containing layer 2005 after being polished.

The second silicon-containing layer 2006 (also referred to as a second polysilicon layer 2006 or simply a polysilicon layer 2006, or a correction film) is formed to correct the film thickness distribution of the first silicon-containing layer 2005 after being polished. More preferably, the second silicon-containing layer 2006 is formed such that the height of the surface of the second silicon-containing layer 2006 is aligned in-plane above the surface of the wafer 200. Here, the height refers to a height up to the surface of the second silicon-containing layer 2006. In other words, the height refers to a distance from the concave structure surface 2002a to the surface of the second silicon-containing layer 2006.

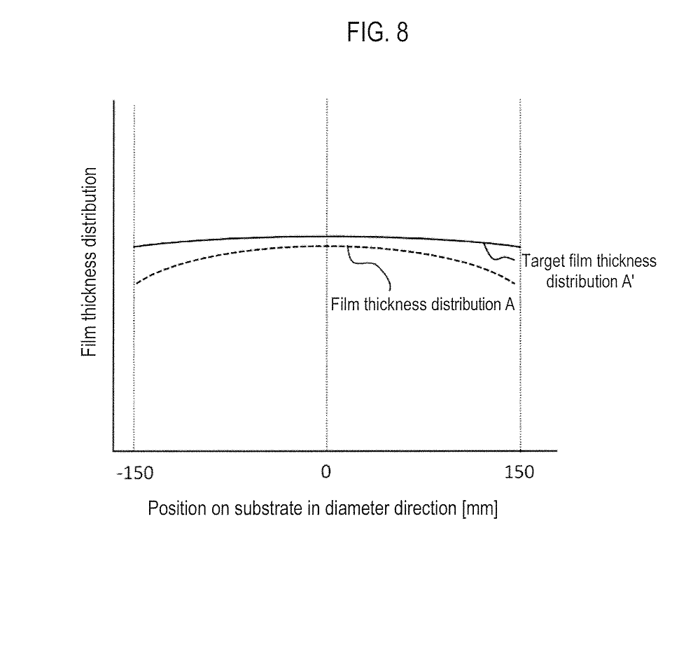

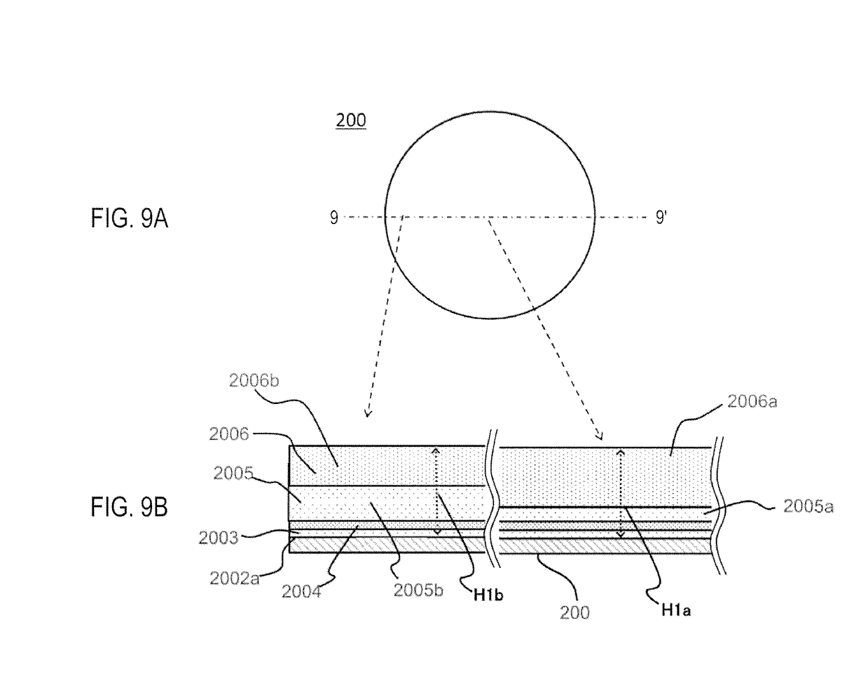

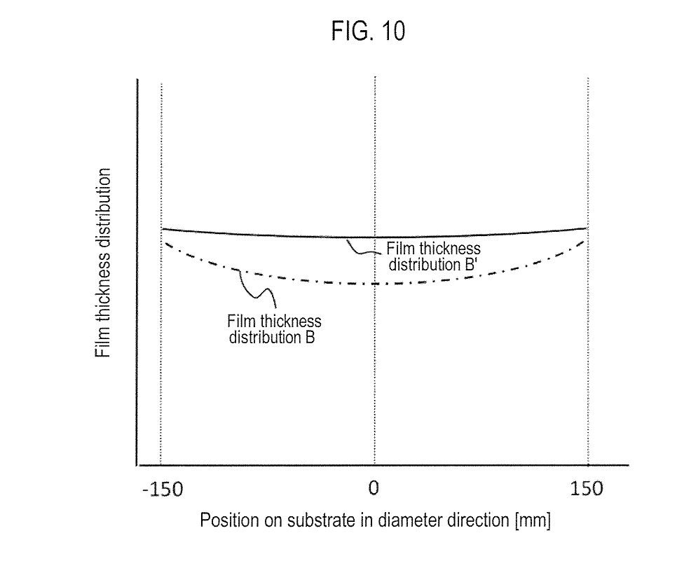

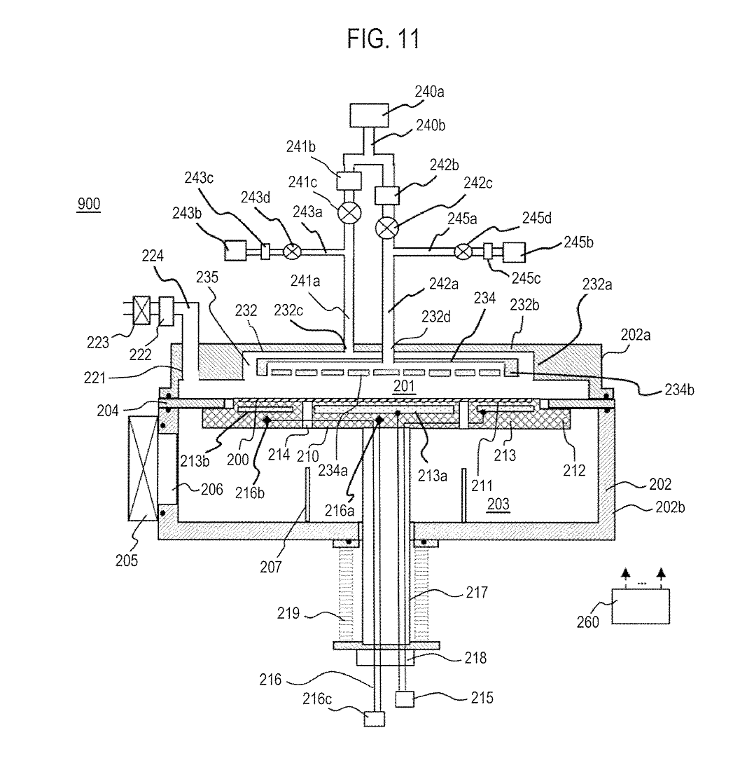

Hereinafter, this step will be described with reference to FIGS. 7A to 13. FIGS. 7A and 7B are views illustrating the second polysilicon layer 2006 formed in this step when the first polysilicon layer 2005 has distribution A. FIG. 8 is an explanatory diagram illustrating the film thickness distribution A and a correction distribution A′ thereof. FIGS. 9A and 9B are views illustrating the second polysilicon layer 2006 formed in this step when the first polysilicon layer 2005 has distribution B. FIG. 10 is an explanatory diagram illustrating the film thickness distribution B and a correction distribution B′ thereof. FIGS. 11 to 13 are explanatory diagrams illustrating a substrate processing apparatus for realizing this step.

FIG. 7A is a top view illustrating the wafer 200 after forming the second polysilicon layer 2006, and FIG. 7B is a cross-sectional view illustrating the center and outer periphery of the wafer 200 extracted from the cross-section taken along line 7-7′ of FIG. 7A.

FIG. 9A is a top view illustrating the wafer 200 after forming the second polysilicon layer 2006, and FIG. 9B is a cross-sectional view illustrating the center and outer periphery of the wafer 200 extracted from the cross-section taken along line 9-9′ of FIG. 9A.

Here, the second polysilicon layer in the central surface of the wafer 200 will be referred to as a polysilicon layer 2006a and the second polysilicon layer in a peripheral surface of the wafer 200 will be referred to as a second polysilicon layer 2006b.

The wafer 200 unloaded from a measurer is loaded to the substrate processing apparatus 900 as a second silicon-containing layer forming apparatus illustrated in FIG. 11.

The substrate processing apparatus 900 controls a film thickness of the polysilicon layer 2006 in-plane above the surface of the substrate based on the data measured in the film thickness measuring step S104. For example, when the data received from the higher apparatus are data representing the distribution A, the substrate processing apparatus 900 controls a film thickness such that the thickness of the polysilicon layer 2006b in the peripheral surface of the wafer 200 becomes thicker, so that the second polysilicon layer 2006a of the central surface thereof becomes thinner than the second polysilicon layer 2006b, as illustrated in FIG. 7B. Further, when the data received from the higher apparatus is data representing the distribution B, the substrate processing apparatus 900 controls a film thickness such that the thickness of the polysilicon layer 2006b in the central surface of the wafer 200 becomes thicker, so that the polysilicon layer 2006b in the outer peripheral surface thereof becomes thinner than the polysilicon layer 2006a, as illustrated in FIG. 9B.

More preferably, when viewed from the concave structure surface 2002a, the thickness of the second polysilicon layer 2006 is controlled such that the height of the polysilicon layer formed by overlapping the first polysilicon layer 2005 and the second polysilicon layer 2006, i.e., the height of the stacked polysilicon film, is placed within a predetermined range in-plane above the surface of the wafer 200. In other words, a film thickness distribution of the second silicon-containing layer is controlled such that a distribution of the heights of the second silicon-containing layer is placed within the predetermined range in-plane above the surface of the substrate. That is, as illustrated in FIGS. 7B and 9B, a height H1a from the concave structure surface 2002a to an upper end of the second polysilicon layer 2006a in the central surface of the wafer 200 and a height H1b from the concave structure surface 2002a to an upper end of the second polysilicon layer 2006b in the peripheral surface of the wafer 200 are aligned.

Subsequently, the substrate processing apparatus 900 capable of controlling a film thickness of each of the polysilicon layers 2006a and 2006b and for forming the second polysilicon layer 2006 will be described in detail.

The substrate processing apparatus 900 according to this embodiment will be described. As illustrated in FIG. 11, the substrate processing apparatus 900 is configured as a single-wafer type substrate processing apparatus.

As shown in FIG. 11, the substrate processing apparatus 900 includes a process vessel 202. The process vessel 202 is configured as, e.g., a flat airtight vessel having a circular horizontal cross-section. Further, the process vessel 202 is formed of a metal material such as, e.g., aluminum (Al) or stainless steel (SUS), or quartz. A process space (process chamber) 201, in which a wafer 200 such as a silicon wafer as a substrate is processed, and a transfer space 203 are formed in the process vessel 202. The process vessel 202 is constituted with an upper vessel 202a and a lower vessel 202b. A partition plate 204 is installed between the upper vessel 202a and the lower vessel 202b. A space, which is surrounded by the upper vessel 202a and is provided above the partition plate 204, is referred to as the process space (also, referred to as the process chamber) 201, and a space, which is surrounded by the lower vessel 202b and is provided below the partition plate 204, is referred to as the transfer space 203.

A substrate loading/unloading port 206 adjacent to a gate valve 205 is formed on a side surface of the lower vessel 202b, and the wafer 200 moves into and out of a transfer chamber (not shown) through the substrate loading/unloading port 206. A plurality of lift pins 207 are installed in a bottom portion of the lower vessel 202b.

A substrate support part 210 configured to support the wafer 200 is installed in the process chamber 201. The substrate support part 210 includes a substrate mounting surface 211 on which the wafer 200 is mounted, and a substrate mounting stand 212 having the mounting surface 211 on a surface thereof. A heater 213 as a heating part is installed inside the substrate mounting stand 212. As the heating part 213 is installed to heat the substrate, the quality of a film formed on the substrate can be improved. Through holes 214 through which the lift pins 207 pass may be formed at positions corresponding to the lift pins 207, respectively, in the substrate mounting stand 212.

The substrate mounting stand 212 is supported by a shaft 217. The shaft 217 passes through a bottom portion of the process vessel 202 and is also connected to an elevation mechanism 218 outside the process vessel 202. By operating the elevation mechanism 218 to elevate or lower the shaft 217 and the substrate mounting stand 212, the wafer 200 loaded on the substrate mounting surface 211 can be elevated or lowered. Further, a periphery of a lower end of the shaft 217 is covered with a bellows 219, so that the inside of the process vessel 202 is kept airtight.

The substrate mounting stand 212 is lowered such that the substrate mounting surface 211 is located at a position of the substrate loading/unloading port 206 (wafer transfer position) when the wafer 200 is transferred, and is elevated until the wafer 200 reaches a processing position (wafer processing position) thereof within the process chamber 201, as shown in FIG. 1, when the wafer 200 is processed.

Specifically, when the substrate mounting stand 212 is lowered to the wafer transfer position, upper end portions of the lift pin 207 protrude from an upper surface of the substrate mounting surface 211 and the lift pins 207 support the wafer 200 from below. Further, when the substrate mounting stand 212 is elevated to the wafer processing position, the lift pins 207 are sunk from the upper surface of the substrate mounting surface 211, and the substrate mounting surface 211 supports the wafer 200 from below. In addition, since the lift pins 207 are in direct contact with the wafer 200, it is preferred to form the lift pins 207 with a material such as, e.g., quartz, alumina or the like. Also, an elevation mechanism may be installed in the lift pins 207 such that the substrate mounting stand 212 and the lift pins 207 move relatively to each other.

The heater 213 has a configuration capable of individually heat-controlling the central surface which is the center of the wafer 200 and the peripheral surface which is the outer periphery of the wafer 200. For example, the heater 213 includes a central zone heater 213a installed in the center of the substrate mounting surface 211 and having a circumferential shape when viewed from above and an outer zone heater 213b having the same shape and installed on the periphery of the central zone heater 213a. The central zone heater 213a heats the central surface of the wafer 200, and the outer zone heater 213b heats the peripheral surface of the wafer 200.

Each of the central zone heater 213a and the outer zone heater 213b is connected to a heater temperature control part 215 through a heater power supply line. The heater temperature control part 215 controls temperatures of the central surface and the peripheral surface of the wafer 200 by controlling power supply to each heater.

A temperature measurer 216a and a temperature measurer 216b for measuring a temperature of the wafer 200 are embedded in the substrate mounting stand 212. The temperature measurer 216a is installed in a central part of the substrate mounting stand 212 to measure a temperature in the vicinity of the central zone heater 213a. The temperature measurer 216b is installed in a peripheral part of the substrate mounting stand 212 to measure a temperature in the vicinity of the outer zone heater 213b. The temperature measurer 216a and the temperature measurer 216b are connected to a temperature information reception part 216c. The temperature information, is measured by each of the temperature measurers, respectively, is transmitted to the temperature information reception part 216c. The temperature information reception part 216c transmits the received temperature information to a controller 260 described later. The controller 260 controls a temperature of the heater based on the received temperature information or etching information described later. Further, the temperature measurer 216a, the temperature measurer 216b and the temperature information reception part 216c is collectively called a temperature detecting part 216.

### (Exhaust System)

An exhaust port 221 is formed on an upper surface of an inner wall of the process chamber 201 (upper vessel 202a) to exhaust atmosphere of the process chamber 201. An exhaust pipe 224 as a first exhaust pipe is connected to the exhaust port 221, and a pressure adjuster 222 such as an auto pressure controller (APC) for controlling the interior of the process chamber 201 to a predetermined pressure and a vacuum pump 223 are serially connected to the exhaust pipe 224 in this order. A first exhaust part (exhaust line) is mainly configured with the exhaust port 221, the exhaust pipe 224 and the pressure adjuster 222. Also, it may be configured by including the vacuum pump 223 in the first exhaust part.

### (Buffer Chamber)

A buffer chamber 232 is installed above the process chamber 201. The buffer chamber 232 is configured by a sidewall 232a and a ceiling 232b. The buffer chamber 232 includes a shower head 234. A gas supply path 235 is formed between an inner wall of the buffer chamber 232 and the shower head 234. That is, the gas supply path 235 is installed to surround an outer wall 234b of the shower head 234.

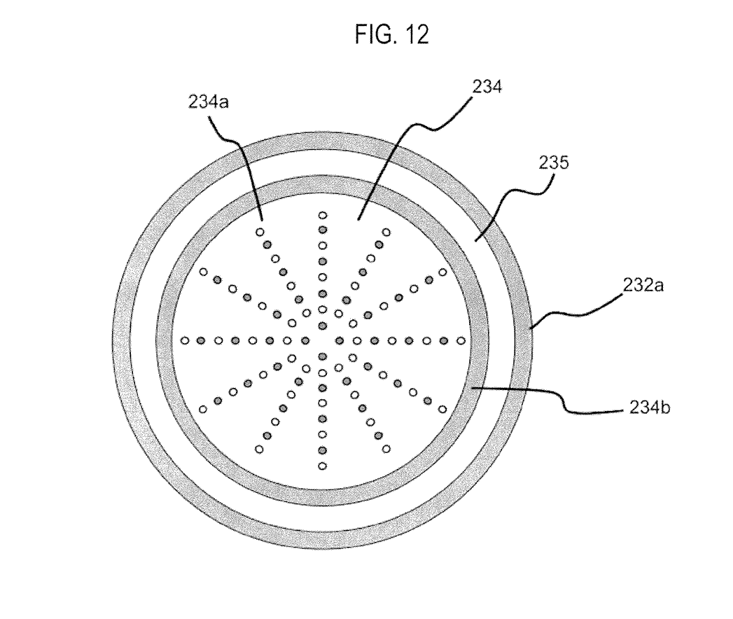

A dispersion plate 234a is installed in the wall that separates the shower head 234 and the process chamber 201. The dispersion plate 234 has, for example, a disc shape. When viewed from the side of the process chamber 201, the gas supply path 235 is positioned between the shower head sidewall 234b and the sidewall 232a, and is installed around the dispersion plate 234a in a horizontal direction, as illustrated in FIG. 12.

A gas supply hole 232c is formed in the ceiling 232b of the buffer chamber 232. A gas supply pipe 241a is connected to the gas supply hole 232c. A through hole 232d is also formed in the ceiling 232b of the buffer chamber 232. A gas supply pipe 242a that passes through the through hole 232d is connected to the ceiling of the shower head 234.

A gas supplied from the gas supply pipe 242a is supplied to the process chamber 201 through the shower head 234. The gas supplied from the gas supply pipe 241a is supplied to the process chamber 201 through the gas supply path 235.

The gas supplied from the shower head 234 is supplied to the central portion of the wafer 200. The gas supplied from the gas supply path 235 is supplied to an edge portion of the wafer 200. The edge portion of the wafer 200 refers to a peripheral surface with respect to the central portion of the wafer 200 described above. The shower head 234 is formed of a material such as, e.g., quartz, alumina, stainless steel, aluminum or the like.

### (Supply System)

A junction pipe 240b, a mass flow controller 241b, and a valve 241c are installed in the gas supply pipe 241a, from an upstream side. A flow rate of a gas that passes through the gas supply pipe 241a is controlled by the mass flow controller 241b and the valve 241c. The junction pipe 240b, a mass flow controller 242b, and a valve 242c are installed in the gas supply pipe 242a from the upstream side. A flow rate of the gas that passes through the gas supply pipe 242a is controlled by the mass flow controller 242b and the valve 242c. A gas source 240a is installed in an upstream side of the junction pipe 240b. The process gas is a silicon-containing gas. For example, disilane (Si₂H₆) is used as the process gas.

Preferably, a first inert gas supply pipe 243a for supplying an inert gas is connected to a downstream side of the valve 241c. An inert gas source 243b, a mass flow controller 243c and a valve 243d are installed in the inert gas supply pipe 243a from the upstream side. As the inert gas, for example, a helium (He) gas is used. The inert gas is added to a process gas flowing in the gas supply pipe 241a, so as to be used as a dilution gas. A concentration or a flow rate of the gas supplied to the process chamber 201 through the gas supply path 235 may be more optimally tuned by controlling the mass flow controller 243c and the valve 243d.

Preferably, a second inert gas supply pipe 245a for supplying an inert gas is installed in a downstream side of the valve 242c. An inert gas source 245b, a mass flow controller 245c and a valve 245d are installed in the inert gas supply pipe 245a from the upstream side. As the inert gas, for example, a helium (He) gas is used. The inert gas is used as a dilution gas of the process gas flowing in the gas supply pipe 242a. A concentration or a flow rate of the gas supplied to the process chamber 201 through the shower head 234 may be more optimally tuned by controlling the mass flow controller 245c and the valve 245d.

The gas supply pipe 241a, the mass flow controller 241b and the valve 241c are collectively called a first gas supply part. Further, the inert gas supply pipe 243a, the mass flow controller 243c and the valve 243d are collectively called a first inert gas supply part. The first inert gas supply part may be included in the first gas supply part. In addition, the junction pipe 240b, the gas source 240a and the gas source 243b may be included in the first gas supply part.

The gas supply pipe 242a, the mass flow controller 242b and the valve 242c are collectively called a second gas supply part. Further, the inert gas supply pipe 245a, the mass flow controller 245c and the valve 245d are collectively called a second inert gas supply part. The second inert gas supply part may be included in the second gas supply part. In addition, the junction pipe 240b, the gas source 240a and the gas source 245b may be included in the second gas supply part.

Also, the first gas supply part, the second gas supply part, the first inert gas supply part, and the second inert gas supply part may be collectively called a gas supply part. In this case, the gas source 240a and the junction pipe 240b may be included in the gas supply part.

In this manner, since the mass flow controllers and the valves are installed in the first gas supply part and the second gas supply part, respectively, an amount of gas may be individually controlled. Further, since the mass flow controllers and the valves are installed in the first inert gas supply part and the second inert gas supply part, respectively, a concentration of gas may be individually controlled.

### (Control Part)

The substrate processing apparatus 900 includes a controller 260 that controls the operations of respective parts of the substrate processing apparatus 900.

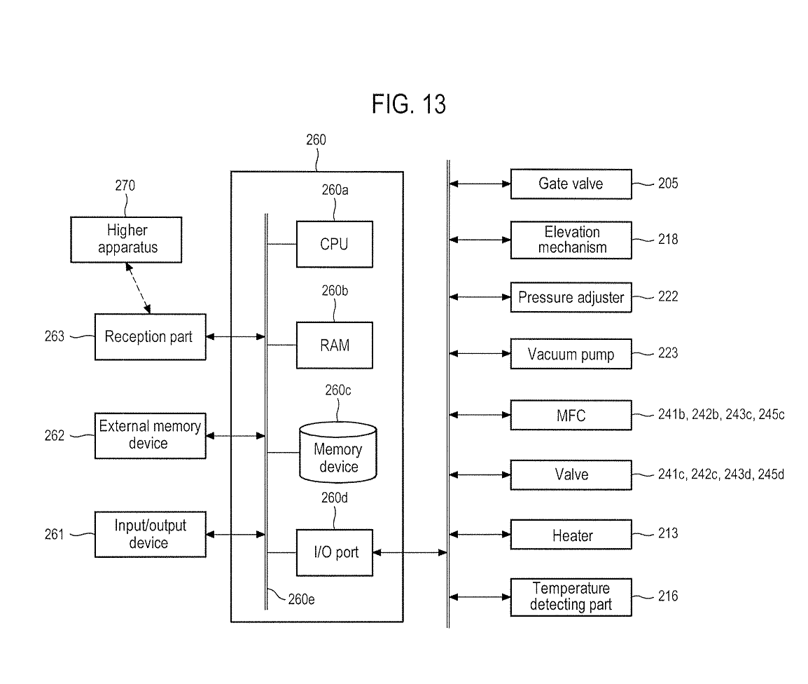

A brief summary of the controller 260 is illustrated in FIG. 13. The controller 260 serving as a control part (controller) is configured as a computer including a central processing unit (CPU) 260a, a random access memory (RAM) 260b, a memory device 260c, and an I/O port 260d. The RAM 260b, the memory device 260c, and the I/O port 260d are configured to exchange data with the CPU 260a via an internal bus 260e. An input/output device 261 configured as, e.g., a touch panel or the like, and an external memory device 262 are connected to the controller 260. In addition, a reception part 263 which is connected to the higher device 270 through the network is installed. The reception part 263 may receive information of other device from the upper device.

The memory device 260c is configured with, for example, a flash memory, a hard disc drive (HDD), or the like. A control program for controlling operations of the substrate processing apparatus, a program recipe in which a sequence, condition, or the like for a substrate processing described later is written, and the like are readably stored in the memory device 260c. In addition, a process recipe, which is a combination of sequences, causes the controller 260 to execute each sequence in a substrate processing process described later in order to obtain a predetermined result, and functions as a program. Hereinafter, the program recipe, the control program, or the like may be generally referred to simply as a program. Further, when the term “program” is used in the present disclosure, it should be understood as including the program recipe, the control program, or a combination of the program recipe and the control program are included. Also, the RAM 260b is configured as a memory area (work area) in which a program, data, or the like read by the CPU 260a is temporarily stored.

The I/O port 121d is connected to the gate valve 205, the elevation mechanism 218, the heater 213, the pressure adjuster 222, the vacuum pump 223 and the like. In addition, the I/O port 121d may also be connected to MFCs 241b, 242b, 243c and 245c, valves 241c, 242c, 243d and 245d, and the like.

The CPU 260a is configured to read and execute the control program from the memory device 260c, and also to read the process recipe from the memory device 260c according to an operation command inputted from the input/output device 261, or the like. Further, the CPU 260a is configured to control the opening/closing operation of the gate valve 205, the elevation operation of the elevation mechanism 218, the operation of supplying power to the heater 213, the pressure adjusting operation by the pressure adjuster 222, the ON/OFF control of the vacuum pump 223, the flow rate adjusting operation of the MFCs, the operation of the valves, and the like, according to the contents of the read process recipe.

In addition, the controller 260 is not limited to being configured as a dedicated computer and may be configured as a general-purpose computer. For example, the controller 260 of this embodiment may be configured by preparing the external memory device 262 storing the program as described above (e.g., a magnetic tape, a magnetic disc such as a flexible disc or a hard disc, an optical disc such as a compact disc (CD) or a digital versatile disc (DVD), a magneto-optical (MO) disc, or a semiconductor memory such as a universal serial bus (USB) memory or a memory card), and installing the program on the general-purpose computer using the external memory device 262. Further, a means for supplying a program to the computer is not limited to the case of supplying the program through the external memory device 123. For example, the program may be supplied using a communication means such as the Internet or a dedicated line, rather than through the external memory device 262. Also, the memory device 260c or the external memory device 262 is configured as a non-transitory computer-readable recording medium. Hereinafter, these will be generally referred to simply as “a recording medium.” Additionally, when the term “recording medium” is used in the present disclosure, it may be understood as including the memory device 260c, the external memory device 262, or both the memory device 260c and the external memory device 262.

Subsequently, a method of forming a film using the substrate processing apparatus 900 will be described.

After the film thickness measuring step S 104, the measured wafer 200 is loaded to the substrate processing apparatus 900. Further, in the following description, the operations of respective parts that constitute the substrate processing apparatus 900 are controlled by the controller 260.

### (Substrate Loading Step)

When the first polysilicon layer 2005 is measured in the film thickness measuring step S104, the wafer 200 is loaded into the substrate processing apparatus 900. Specifically, the substrate support part 210 is lowered by the elevation mechanism 218 such that the lift pins 207 protrude from the through holes 214 toward an upper surface side of the substrate support part 210. Also, after an internal pressure of the process chamber 201 is adjusted to predetermined pressure, the gate valve 205 is opened and the wafer 200 is loaded on the lift pins 207 from the gate valve 205. After the wafer 200 is loaded on the lift pins 207, the substrate support part 210 is elevated to a predetermined position by the elevation mechanism 218, so that the wafer 200 is loaded on the substrate support part 210 from the lift pins 207.

### (Decompression and Temperature Rising Step)

Thereafter, the interior of the process chamber 201 is exhausted through the exhaust pipe 224 such that the interior of the process chamber 201 reaches a predetermined pressure (degree of a vacuum). At this time, a degree of valve opening of an APC valve as the pressure adjuster 222 is feedback-controlled based on a pressure value measured by a pressure sensor. Further, based on the temperature value detected by the temperature detecting part 216, an amount of current to the heater 213 is feedback-controlled such that the interior of the process chamber 201 is set to be a predetermined temperature. Specifically, the substrate support part 210 is preheated by the heater 213, and after temperature variation in the wafer 200 or the substrate support part 210 disappears, the substrate support part 210 is left for a predetermined period of time. During this period, when moisture remains in the process chamber 201, or degassing occur from a member, these may be removed by vacuum-exhausting or purging by supplying an inert gas. By doing so, a preparation before a film forming process is completed. Also, when the interior of the process chamber 201 is exhausted to a predetermined pressure, the interior of the process chamber 201 may be vacuum-exhausted up to the degree of a vacuum degree, which can reach once.

After the wafer 200 is loaded on the substrate support part 210 and the atmosphere within the process chamber 201 is stabilized, the mass flow controller 241b and the mass flow controller 242b are actuated and the opening degrees of the valve 241c and the valve 242c are also adjusted. At this time, the mass flow controller 243c and the mass flow controller 245c may be actuated and the opening degrees of the valve 243d and the valve 245d may also be adjusted.

### (Gas Supply Step)

In a gas supply step, a gas is supplied to the peripheral surface of the wafer 200 through the gas supply path 235 from the first gas supply part. In parallel with this, a gas is supplied to the central surface of the wafer 200 through the buffer chamber 232 from the second gas supply part.

When the gas is supplied, an amount (or a concentration) of a gas supplied to the central surface of the wafer 200 and an amount (or a concentration) of a gas supplied to the peripheral surface are respectively controlled by controlling the first gas supply part and the second gas supply part according to the film thickness measurement data of the polysilicon layer 2005 received from the higher apparatus 270. More preferably, an in-plane temperature gradient of the wafer 200 is controlled by controlling the central zone heater 213a and the outer zone heater 213b according to the measurement data received from the higher apparatus 270.

The gas supplied into the process chamber is decomposed within the process chamber to form the second polysilicon layer 2006 on the first polysilicon layer 2005.

When a predetermined period of time has lapsed, the valve 241c, the valve 242c, the valve 243d and the valve 245d are closed to stop the supply of each gas.

The temperature of the heater 213 at this time is set to fall within a range of 200 to 750 degrees C., preferably, 300 to 600 degrees C., more preferably, 300 to 550 degrees C., with respect to the wafer 200. As the inert gas, in addition to the helium (He) gas, any gas may be used as long as it does not adversely affect the film. For example, a rare gas such as Ar, N₂, Ne, Xe or the like may be used.

### (Substrate Unloading Step)

After the film forming step is finished, the substrate support part 210 is lowered by the elevation mechanism 218 such that the lift pins 207 protrude to an upper surface side of the substrate support part 210 from the through hole 214. Further, after the internal pressure of the process chamber 201 is adjusted to a predetermined pressure, the gate valve 205 is released and the wafer 200 is transferred from the lift pins 207 to the outside of the gate valve 205.

Subsequently, a method for controlling a film thickness of the second polysilicon layer 2006 by using this apparatus will be described. As described above, after the CMP step S103 is completed, the first polysilicon layer 2005 has film thicknesses different in the central surface and the peripheral surface of the wafer 200. In the measuring step S104, a film thickness distribution thereof is measured. The measurement result is stored in a RAM 260b through the higher apparatus 270. The stored data is compared with a recipe within a memory device 260c and the apparatus is controlled based on the recipe.

Subsequently, a case in which the data stored in the RAM 260b has distribution A will be described. The case of distribution A refers to a case in which the polysilicon layer 2005a is thicker than the polysilicon layer 2005b, as illustrated in FIG. 6.

In case of distribution A, in this step, the polysilicon layer 2006b formed in the peripheral surface of the wafer 200 is controlled to have a greater film thickness and the polysilicon layer 2006a formed in the central surface of the wafer 200 is controlled to have a film thickness smaller than that of the polysilicon layer 2006b. Specifically, when a gas is supplied, the first gas supply part is controlled to supply an amount of gas more than that of the second gas supply part. By doing so, the height of the polysilicon layer, i.e., the film thickness of the polysilicon film formed by overlapping the polysilicon layer 2006 on the polysilicon layer 2005, in the present semiconductor device, can be corrected like a target film thickness distribution A′ illustrated in FIG. 8.

At this time, the mass flow controller 241b is controlled and an opening degree of the valve 241c is also controlled in the first gas supply part to control an amount of gas supplied from the gas supply path 235 to the process chamber 201. Also, the mass flow controller 242b is controlled and an opening degree of the valve 242c is also controlled in the second gas supply part to control an amount of gas supplied from the shower head 234 to the process chamber 201. An exposure amount of the process gas (silicon-containing gas) per unit area on the surface of the wafer 200 is controlled such that an exposure amount of the process gas supplied from the gas supply path 235 is greater than that of the process gas supplied from the shower head 234.

The process gas supplied through the shower head 234 is supplied to the polysilicon layer 2005a formed on the central surface of the wafer 200. The supplied gas is used to form the polysilicon layer 2006a on the polysilicon layer 2005a, as illustrated in FIG. 7B.

The process gas supplied through the gas supply path 235 is supplied to the polysilicon layer 2005b formed on the peripheral surface of the wafer 200. The supplied gas is used to form the polysilicon layer 2006b on the polysilicon layer 2005b, as illustrated in FIG. 7B.

As described above, since the exposure amount of the process gas per unit area on the surface of the wafer 200 is greater on the polysilicon layer 2005b than on the polysilicon layer 2005a, a film thickness of the polysilicon layer 2006b can be greater than that of the polysilicon layer 2006a.

At this time, as illustrated in FIG. 7B, the thickness of the polysilicon layer 2006 is controlled such that a thickness H1b overlapping the polysilicon layer 2006b on the polysilicon layer 2005b and a thickness H1a overlapping the polysilicon layer 2006a on the polysilicon layer 2005a are substantially equal to each other. More preferably, a distance from the surface of the substrate to an upper end of the second silicon-containing layer is controlled to fall within a predetermined range. Further, more preferably, a film thickness distribution of the polysilicon layer 2006 is controlled such that a distribution of the height of the polysilicon layer 2006 in-plane above the surface of the substrate (i.e., upper end of the polysilicon layer 2006) falls within a predetermined range.

In addition, in another method, the supply amounts of the process gases of the gas supply pipe 241a and the gas supply pipe 242a are set to be equal to each other, while a concentration of the silicon-containing gas of each of the gas supply pipe 241a and the gas supply pipe 242a is controlled. In controlling the concentration of the process gas, the concentration of the process gas that passes through the gas supply pipe 241a is controlled by controlling the first inert gas supply part. Further, the concentration of the process gas that passes through the gas supply pipe 242a is controlled by controlling the second inert gas supply part. In case of distribution A, the concentration of the process gas that passes through the gas supply pipe 241a is increased, while the concentration of the process gas that passes through the gas supply pipe 242a is set to be lower than that of the gas that passes through the gas supply pipe 241a.

By doing so, the exposure amount of the process gas per unit area on the surface of the wafer 200 can be more minutely controlled such that the amount of gas supplied from the gas supply path 235 is greater than that of the gas supplied from the shower head 234. Accordingly, it is more reliably possible that the film thickness of the polysilicon layer 2006b is greater than that of the polysilicon layer 2006a.

More preferably, the supply amounts of the process gasses via the gas supply pipe 241a and the gas supply pipe 242a are set to be different from each other and the concentrations thereof are also set to be different from each other. Through this controlling, the process gases can be supplied in a greater difference in the exposure amounts of the process gases per unit area. That is, the polysilicon layer 2006a and the polysilicon layer 2006b can be formed in a greater difference in the film thickness. Thus, in the CMP step S103, even though the difference in height between the polysilicon layer 2005a and the polysilicon layer 2005b becomes greater, it is possible to align the heights.

Further, more preferably, in parallel with controlling the process gases as described above, the central zone heater 213a and the outer zone heater 213b may be controlled. Since the thickness of the film to be formed is proportional to a temperature, in case of distribution A, a temperature of the outer zone heater 213b is set to be higher than that of the central zone heater 213a. For example, this is effective when the polysilicon layer 2006 is formed using a gas, which significantly contributes to film formation efficiency according to a temperature condition, like disilane.

In this manner, it can be more minutely controlled by controlling the supply amount (concentration) of the process gas in parallel with the temperature.

In case of distribution B, in this step, the polysilicon layer 2006a formed in the central surface of the wafer 200 is controlled to have a greater film thickness and the polysilicon layer 2006b formed in the peripheral surface of the wafer 200 is controlled to have a film thickness smaller than that of the polysilicon layer 2006a. Specifically, when supplying a gas, the second gas supply part is controlled to supply a larger amount of process gas than that of the first gas supply part. By doing so, the height of the polysilicon layer, i.e., the film thickness of the polysilicon film overlapping the polysilicon layer 2006 on the polysilicon layer 2005, in the present semiconductor device, can be corrected like a target film thickness distribution B′ illustrated in FIG. 10.

At this time, in the first gas supply part, the mass flow controller 241b is controlled and an opening degree of the valve 241c is also controlled to control an amount of gas supplied from the gas supply path 235 to the process chamber 201. Also, in the second gas supply part, the mass flow controller 242b is controlled and an opening degree of the valve 242c is controlled to control an amount of gas supplied from the shower head 234 to the process chamber 201. An exposure amount of the process gas (silicon-containing gas) per unit area on the surface of the wafer 200 is controlled such that an exposure amount of the process gas supplied from the shower head 234 is greater than that of the process gas supplied from the gas supply path 235.

The process gas supplied through the shower head 234 is supplied to the polysilicon layer 2005a formed on the central surface of the wafer 200. The supplied gas is used to form the polysilicon layer 2006a on the polysilicon layer 2005a, as illustrated in FIG. 9B.

The process gas supplied through the gas supply path 235 is supplied to the polysilicon layer 2005b formed on the peripheral surface of the wafer 200. The supplied gas is used to form the polysilicon layer 2006b on the polysilicon layer 2005b, as illustrated in FIG. 9B.

As described above, since the exposure amount of the process gas per unit area on the surface of the wafer 200 is greater on the polysilicon layer 2005a than on the polysilicon layer 2005b, a film thickness of the polysilicon layer 2006a can be greater than that of the polysilicon layer 2006b.

At this time, as illustrated in FIG. 9B, the thickness of the polysilicon layer 2006 is controlled such that a thickness H1b overlapping the polysilicon layer 2006b on the polysilicon layer 2005b and a thickness H1a overlapping the polysilicon layer 2006a on the polysilicon layer 2005a are substantially equal to each other. More preferably, a distance from the surface of the substrate to an upper end of the second silicon-containing layer is controlled to fall within a predetermined range. Further, more preferably, a film thickness distribution of the polysilicon layer 2006 is controlled such that a distribution of the height of the polysilicon layer 2006 in-plane above the surface of the substrate (i.e., upper end of the polysilicon layer 2006) falls within a predetermined range.

In addition, in another method, the supply amounts of the process gases of the gas supply pipe 241a and the gas supply pipe 242a are set to be equal to each other, while a concentration of the silicon-containing gas of each of the gas supply pipe 241a and the gas supply pipe 242a is controlled. In controlling the concentration of the process gas, the concentration of the process gas that passes through the gas supply pipe 241a is controlled by controlling the first inert gas supply part. Also, the concentration of the process gas that passes through the gas supply pipe 242a is controlled by controlling the second inert gas supply part. In case of distribution B, the concentration of the process gas that passes through the gas supply pipe 242a is increased, while the concentration of the process gas that passes through the gas supply pipe 241a is set to be lower than that of the gas that passes through the gas supply pipe 242a.

By doing so, the exposure amount of the process gas per unit area on the surface of the wafer 200 can be more minutely controlled such that the amount of gas supplied from the shower head 234 is greater than that of the gas supplied from the gas supply path 235. Accordingly, it is more reliably possible that the film thickness of the polysilicon layer 2006a is greater than that of the polysilicon layer 2006b.

More preferably, the supply amounts of the process gasses via the gas supply pipe 241a and the gas supply pipe 242a are set to be different from each other and the concentrations thereof are also set to be different from each other. Through this controlling, the process gases can be supplied in a greater difference in the exposure amounts of the process gases per unit area. That is, the polysilicon layer 2006a and the polysilicon layer 2006b can be formed in a greater difference in the film thickness. Thus, in CMP step S103, even though the difference in height between the polysilicon layer 2005a and the polysilicon layer 2005b becomes greater, it is possible to align the heights.

Further, more preferably, in parallel with controlling the process gases as described above, the central zone heater 213a and the outer zone heater 213b may be controlled. Since the thickness of the film to be formed is proportional to a temperature, in case of distribution B, a temperature of the central zone heater 213a is set to be higher than that of the outer zone heater 213b. For example, this is effective when the polysilicon layer 2006 is formed using a gas, which significantly contributes to film formation efficiency according to a temperature condition, like disilane.

In this manner, it can be more minutely controlled by controlling the supply amount (concentration) of the process gas in parallel with the temperature.

### (Film Thickness Measuring Step S106)

Subsequently, a film thickness measuring step S106 will be described. In the film thickness measuring step S106, a height of the stacked polysilicon film overlapping the first polysilicon layer 2005 and the second polysilicon layer 2006 is measured. Specifically, it is checked whether the height of the overlapped layer is aligned, that is, whether a film thickness of the stacked polysilicon film has been corrected like a target film thickness distribution. Here, the expression “height is aligned” may not be limited to a case heights are completely identical to each other, but may be a case having a height difference. For example, the height difference may be a difference within a range that does not affect an exposure process or an etching process described later.

When the distribution of heights in-plane above the surface of the wafer 200 falls within a predetermined range, the process proceeds to a nitride film forming step S107. Also, in a case in which it has been already known that the film thickness distribution is a predetermined distribution, the film thickness measuring step S106 may be omitted.

### (Nitride Film Forming Step S107)

Next, a nitride film forming step S107 will be described.

After the film thickness is measured, the wafer 200 is loaded to a nitride film forming apparatus. The nitride film forming apparatus is a general single-wafer type apparatus, and thus, a description thereof will be omitted.

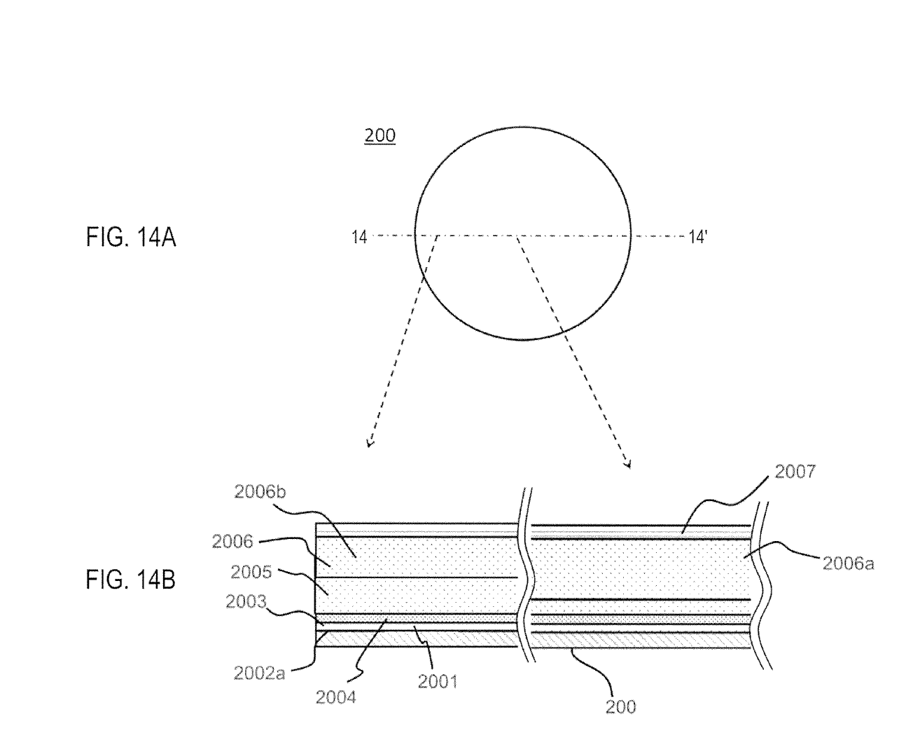

In this step, as illustrated in FIGS. 14A and 14B, a silicon nitride film 2007 is formed on the second polysilicon layer 2006. The silicon nitride film serves as a hard mask during an etching process described later. Further, in FIGS. 14A and 14B, although distribution A is illustrated as an example, it is not limited thereto. Also, it should be understood that distribution B is the same as that of the distribution A.

In the nitride film forming apparatus, a silicon-containing gas and a nitrogen-containing gas are supplied into the process chamber to form the silicon nitride film 2007 on the wafer 200. The silicon-containing gas is, for example, disilane (SiH₄), and the nitrogen-containing gas is, for example, ammonia (NH₃).

Since the silicon nitride film 2007 is formed on the polysilicon film with a height aligned in the second polysilicon layer forming step, a height of the silicon nitride film also has a height distribution within a predetermined range in-plane above the surface of the substrate. That is, in-plane above the surface of the wafer 200, a distance from the concave structure surface 2002a to the surface of the nitride film 2007 falls within a predetermined range in-plane above the surface of the wafer 200.

### (Film Thickness Measuring Step S108)

Subsequently, a film thickness measuring step S108 will be described. In the film thickness measuring step S108, a height of the layer overlapping the first polysilicon layer 2005, the second polysilicon layer 2006 and the silicon nitride film 2007 is measured. When the height is within a predetermined range, the process proceeds to a patterning step S109. Here, the expression “height is within a predetermined range” may not be limited to a case which heights are completely identical to each other, and may be a case having a height difference. For example, the height difference may be a difference within a range that does not affect an etching process or a metal film forming process which is a subsequent process. Also, in a case in which it has already been known that the height of the layer overlapping the first polysilicon layer, the second polysilicon layer and the silicon nitride film is within a predetermined value in advance, the film thickness measuring step S108 may be omitted.

### (Patterning Step S109)

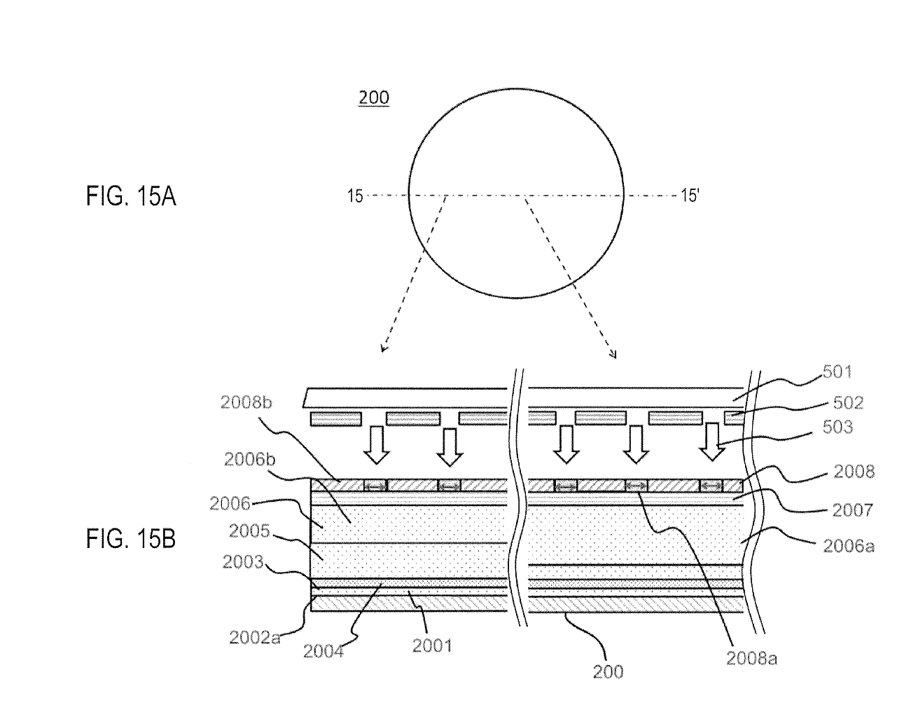

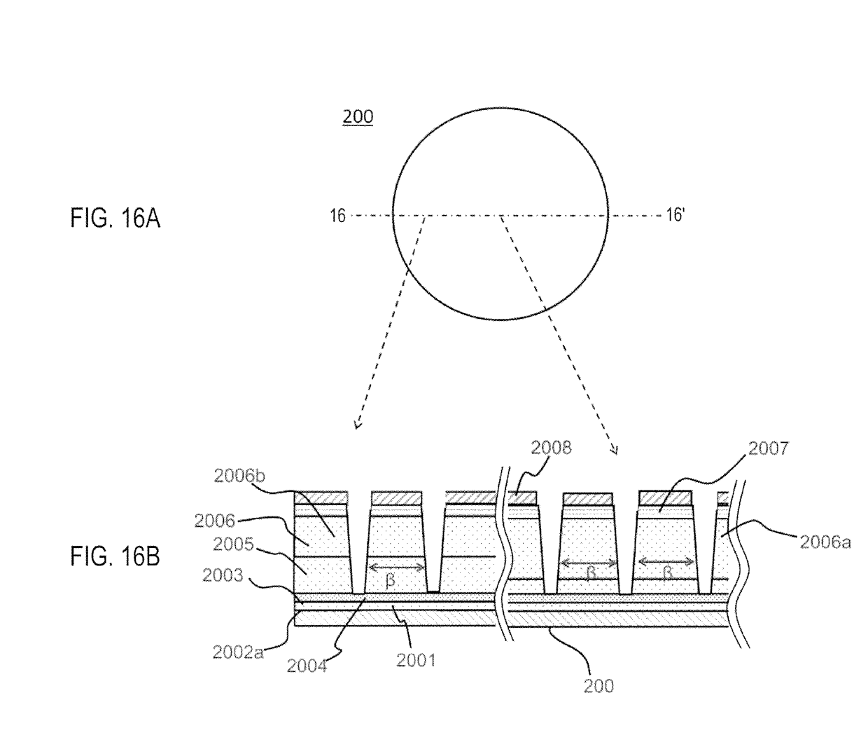

Subsequently, a patterning step S109 will be described with reference to FIGS. 15A and 15B, and FIGS. 16A and 16B. FIGS. 15A and 15B are explanatory views illustrating the wafer 200 during an exposure process. FIGS. 16A and 16B are explanatory views illustrating the wafer 200 after an etching process.

Hereinafter, details thereof will be described.

After the silicon nitride film is formed, a resist film 2008 is coated on the silicon nitride film. Thereafter, an exposure process is performed by emitting light from a lamp 501. During the exposure process, light 503 is irradiated onto the resist film 2008 through a mask 502 to reform a portion of the resist film 2008. Here, the reformed resist film will be referred to as a resist film 2008a, and a non-reformed resist film will be referred to as a resist film 2008b.

As described above, a height from the concave structure surface 2002a to a surface of the nitride film 2007 is within a predetermined range in-plane above the surface of the substrate. Thus, the height from the concave structure surface 2002a to the surface of the resist film 2008 can be aligned. During the exposure process, a distance which light reaches the resist, i.e., a movement distance of the light 503, becomes equalized in-plane above the surface of the wafer 200. Thus, an in-plane distribution of a depth of focus can be equalized.

Since it is able to equalize the depth of focus, a width of the resist film 2008a can be uniform in-plane above the surface of the substrate as illustrated in FIG. 15B. Thus, variation in the pattern width can be eliminated.

Subsequently, a state of the wafer 200 after the etching process will be described with reference to FIGS. 16A and 16B. As described above, since the width of the resist film 2008a is uniform, it is possible to make an etching condition uniform in-plane above the surface of the wafer 200. Thus, an etching gas can be uniformly supplied to the central surface or the peripheral surface of the wafer 200, and a width β of the polysilicon layer after etching (hereinafter, referred to as a pillar) can be uniform. Since the width β is uniform in-plane above the surface of the wafer 200, the characteristics of the gate electrode can be uniform in-plane above the surface of the substrate, thereby improving yield.

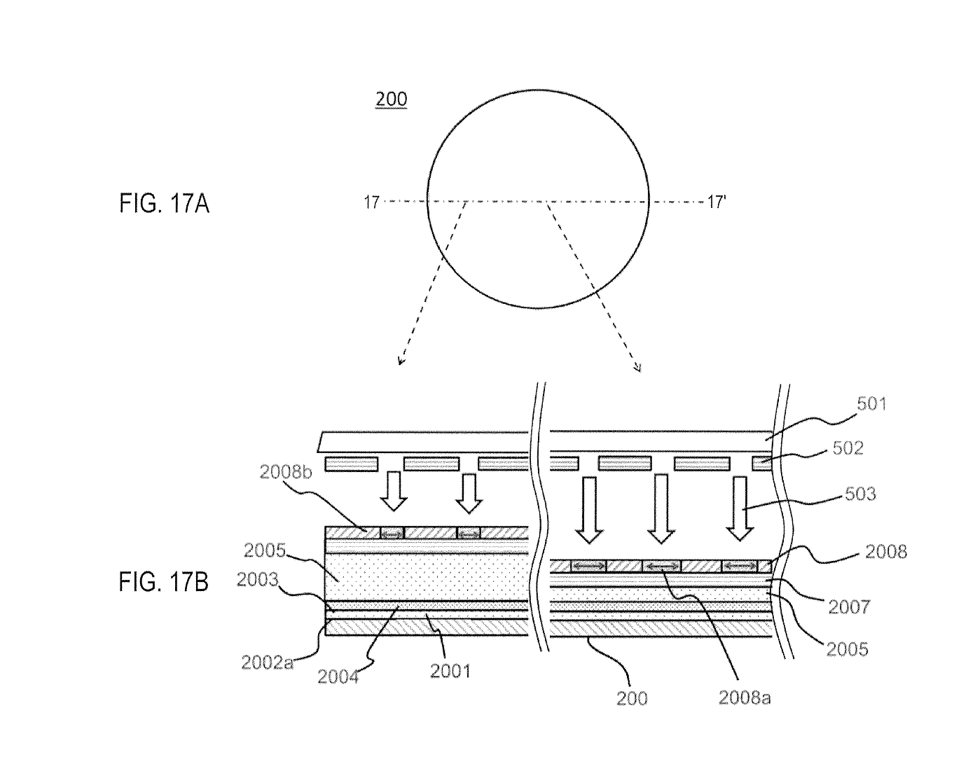

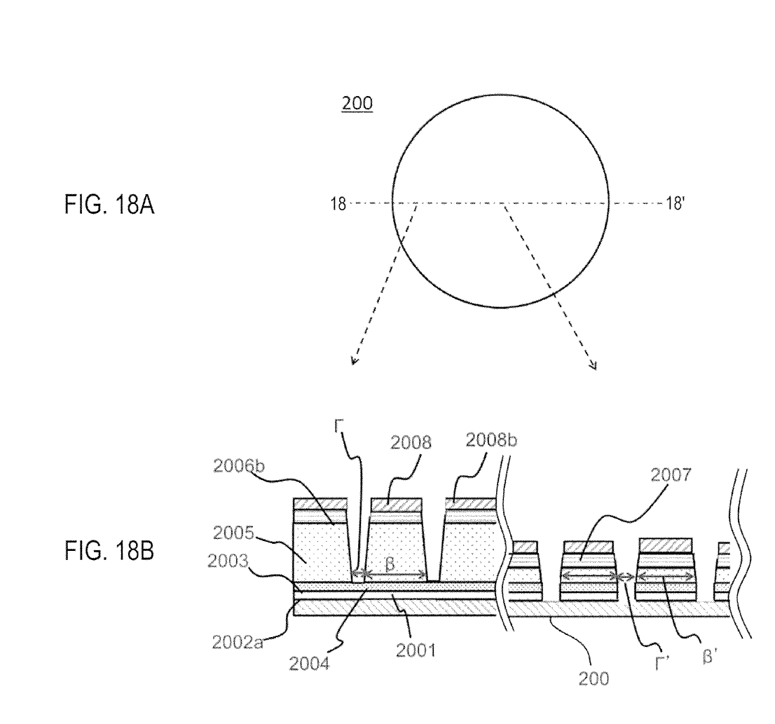

Subsequently, comparative examples will be described with reference to FIGS. 17A and 17B, and FIGS. 18A and 18B. The comparative examples are cases in which the second silicon-containing layer forming step S105 is not performed. Thus, the heights of the wafer 200 in the central surface and the peripheral surface thereof are different from each other.

First, a first comparative example will be described with reference to FIGS. 17A and 17B. FIGS. 17A and 17B are views for comparison with FIGS. 15A and 15B. In FIGS. 17A and 17B, since the heights of the polysilicon layer are different at the central surface and the peripheral surface of the wafer 200, distances of light 503 at the central surface of the wafer 200 and the peripheral surface of the wafer 200 are different from each other. Thus, focal lengths are different at the central surface and the peripheral surface, resulting in a difference in width of the resist film 2008a in-plane above the surface of the substrate. When a process is performed on such resist film 2008, widths of pillars become different from one another after an etching process, so that the characteristic variation occurs.

In contrast, in this embodiment, since the second silicon-containing layer forming step S105 is performed, widths of the pillars in-plane above the surface of the wafer are uniform. Thus, compared with the comparative example, the semiconductor device having uniform characteristics can be formed, thereby considerably contributing to improvement of yield.

Subsequently, a second comparative example will be described with reference to FIGS. 18A and 18B. FIGS. 18A and 18B are views for comparison with FIGS. 16A and 16B. FIGS. 18A and 18B are explanatory views illustrating, for example, a case in which variation in widths of the resist film 2008a in the central surface of the wafer 200 and the peripheral surface of the wafer 200 does not occur. That is, it refers to a case in which variation in the widths of the gaps (portions removing the resist film 2008a) in the resist film 2008a does not occur.

After the resist film 2008b is removed, an etching process is performed. When the polysilicon film is removed in the etching process, the heights of the polysilicon film at the central surface of the wafer 200 and the peripheral surface of the wafer 200 are different from each other. Thus, for example, when an etching time is set according to an etching amount of the height of the central surface, a desired amount can be etched in the central surface, but an object to be etched remains in the peripheral surface. Meanwhile, when the central surface is etched according to an etching amount of the height of the periphery, a desired amount can be etched in the peripheral surface, but in the central surface, a sidewall of the pillar, the insulating film 2004, or the device isolation film 2003 is etched.

When the sidewall of the pillar is etched, distances Γ between the polysilicon films of the pillars become different in the central surface and the peripheral surface of the wafer 200. That is, the widths β of the polysilicon films of the pillars are different in the central surface and the peripheral surface of the wafer 200.

The characteristic of an electrode is easily affected by the width β and thus, when the width β is varied, the characteristic of an electrode to be formed are also varied. Thus, the variation of the width β causes a degradation of yield.

In contrast, in this embodiment, since the height of the polysilicon film is aligned, it is possible to align the width of the pillar in both the central surface and the peripheral surface of the wafer 200. Thus, yield can be enhanced.

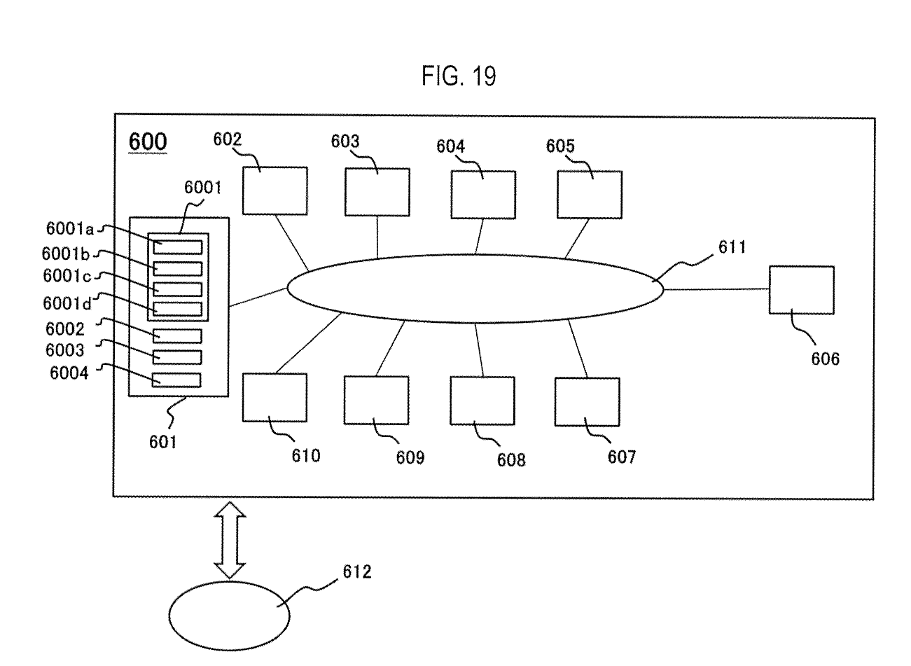

Further, in this embodiment, although it has been described that the gate insulating film forming step S101 to the patterning step S109 are performed in the individual apparatuses, respectively, it is not limited thereto and the steps may be performed in a whole system as illustrated in FIG. 19. Here, the system 600 includes a higher apparatus 601 for controlling the system. The system 600 includes an insulating film forming apparatus 602 configured to perform the gate insulating film forming step S101, a substrate processing apparatus 603 configured to perform the first silicon-containing layer forming step S102, a polishing apparatus 604 (equivalent to the polishing apparatus 400 of the present embodiment) configured to perform the CMP step S103, a film thickness measuring apparatus 605 configured to perform the film thickness measuring step S104, a substrate processing apparatus 606 (equivalent to the substrate processing apparatus 900 of present embodiment) configured to perform the second silicon-containing layer forming step S105, a film thickness measuring apparatus 607 configured to perform the film thickness measuring step S106, a nitride film forming apparatus 608 configured to perform the nitride film forming step S107, a measuring apparatus 609 configured to perform the film thickness measuring step S108, and a patterning system 610 configured to perform the patterning step S109, as a substrate processing apparatus or a substrate processing system for processing a substrate. In addition, the system 600 includes a network 611 for exchanging information between the apparatuses or systems.

The apparatuses of the system 600 can be appropriately selected, and apparatuses for performing the functions thereof may be integrated into a single apparatus. In addition, the apparatuses may be managed by other system, instead of managing in the system 600. In this case, information may be transmitted to the other system through a higher network 612.

The higher apparatus 601 includes a controller 6001 for controlling information transmission of each substrate processing apparatus or substrate processing system.

The controller 6001 serving as a control part (controller) is configured as a computer including a central processing unit (CPU) 6001a, a random access memory (RAM) 6001b, a memory device 6001c, and an I/O port 6001d. The RAM 6001b, the memory device 6001c, and the I/O port 6001d are configured to exchange data with the CPU 6001a via an internal bus. An input/output device 6002 configured as, e.g., a touch panel or the like, and an external memory device 6003 are connected to the controller 6001. In addition, a transceiving part 6004 for transceiving information to/from other apparatus or system through the network is installed.

The memory device 6001c is configured with, for example, a flash memory, a hard disc drive (HDD), or the like. A program for instructing the substrate processing apparatus to operate, and the like are readably stored in the memory device 6001c. Further, the RAM 6001b is configured as a memory area (work area) in which a program, data, or the like read by the CPU 6001a is temporarily stored.

The CPU 6001a is configured to read and execute the control program from the memory device 6001c, and also to read the program from the memory device 6001c according to an input of an operation command from the input/output device 6002, or the like. Further, the CPU 6001a is configured to be able to control the information transmission operation of each apparatus to carry out the contents of the read program.

In addition, the controller 6001 is not limited to a case configured as a dedicated computer and may be configured as a general-purpose computer. For example, the controller 6001 of present embodiment may be configured by preparing the external memory device 6003 (e.g., a magnetic tape, a magnetic disc such as a flexible disc or a hard disc, an optical disc such as a CD or DVD, a magneto-optical (MO) disc, or a semiconductor memory such as a USB memory or a memory card), in which the program is stored, and installing the program on the general-purpose computer using the external memory device 6003. Further, a means for supplying a program to the computer is not limited to the case of supplying the program through the external memory device 6003. For example, the program may be supplied using a communication means such as the Internet or a dedicated line, rather than through the external memory device 6003. Also, the memory device 6001c or the external memory device 6003 is configured as a non-transitory computer-readable recording medium. Hereinafter, these means for supplying the program will be generally referred to simply as “a recording medium”. Additionally, when the term “recording medium” is used herein, it should be understood as including only the memory device 6001c, only the external memory device 6003, or both the memory device 6001c and the external memory device 6003.

Further, in the foregoing embodiment, although it has been described that the wafer 200 is divided into the center and the periphery, it is not limited thereto and a film thickness of the silicon-containing film may be controlled in more subdivided regions with respect to a diameter direction. For example, the substrate may be divided into three regions such as the center of the substrate, the periphery of the substrate, and a space between the center and the periphery.

In addition, here, although the silicon nitride film is described as an example of a hard mask, it is not limited thereto and a silicon oxide film, for example, may be used as the hard mask.

Also, film formation processing such as CVD, oxidation, nitridation, or oxynitridation may be performed to bury an uneven structure. Through this processing, correction may be performed even when an uneven structure cannot be reduced through migration or sputtering.

Also, when sputtering or film formation processing is performed, anisotropic processing or isotropic processing may be combined. By combining anisotropic processing or isotropic processing, a correction may be performed more precisely.

Also, a pattern is not limited to the silicon oxide film or the silicon nitride film and may be formed by an oxide film, a nitride film, a carbide film, an oxynitride film a metal film or a composite film thereof, which contains different elements.

Also, in the foregoing description, although the processing of one process on the manufacturing process of a semiconductor device has been described, the processing is not limited thereto and may be applied to techniques of processing a substrate, such as patterning processing of a liquid crystal panel manufacturing process, patterning processing of a solar cell manufacturing process, or patterning processing of a power device manufacturing process.

Also, in the foregoing description, although the first gas supply part and the second gas supply part are controlled, and the central zone heater 213a and the outer zone heater 213b are controlled such that a gas supply amount (concentration) are different according to the distribution of the first polysilicon film, the control is not limited thereto. For example, when it is difficult to change an amount or a concentration of a gas in the gas supply parts, the supply amounts of the first gas supply part and the second gas supply part may be controlled to be equal to each other and the temperatures of the central zone heater 213a and the outer zone heater 213b may be controlled to be different from each other.

Also, in the foregoing description, although different apparatuses are used in the first silicon-containing layer forming step and the second silicon-containing layer forming step, the apparatuses are not limited thereto. For example, the first silicon-containing layer forming step may be actually performed in the substrate processing apparatus 900.

Also, the foregoing steps can be applied to the wafer of 300 mm in diameter, and when a large substrate such as a wafer of 450 mm in diameter is used, it may be more effective. The reason is because the CMP step S103 remarkably influence on the large substrate. That is, a film thickness difference between the polysilicon layer 2005a and the polysilicon layer 2005b becomes greater. By performing the second silicon-containing layer forming step, the variation in in-plane characteristics even in a large substrate may be suppressed.

### <Aspects of the Present Disclosure>

Hereinafter, some aspects of the present disclosure will be supplemented.

### (Supplementary Note 1)

According to one aspect of the present disclosure, there is provided a method of manufacturing a semiconductor device or a substrate processing method, including: forming an insulating film on a channel region formed on a substrate; forming a first silicon-containing layer formed as a portion of a silicon-containing film on the insulating film; polishing the substrate; measuring a film thickness distribution of the first silicon-containing film in-plane above the surface of the substrate; and forming a second silicon-containing layer as a portion of the silicon-containing film on the first silicon-containing layer after being polished to have a film thickness distribution different from the film thickness distribution, thereby correcting a film thickness of the silicon-containing film.

### (Supplementary Note 2)

In the method according to Supplementary Note 1, preferably, the silicon-containing layer is formed of polysilicon.

### (Supplementary Note 3)

The method according to Supplementary Note 1 or 2, preferably includes forming a predetermined pattern on the substrate after the act of forming a second silicon-containing layer.

### (Supplementary Note 4)

In the method according to any one of Supplementary Note 3, preferably, the act of forming a predetermined pattern includes performing an exposure process on the substrate, and in the act of forming a second silicon-containing layer, a film thickness distribution of the second silicon-containing layer in-plane above the surface of the substrate is controlled such that a distribution of a depth of focus in-plane above the surface of the substrate is within a predetermined range during the act of performing an exposure process.

### (Supplementary Note 5)

In the method according to any one of Supplementary Notes 1 to 4, preferably, when a film thickness distribution of the first silicon-containing layer indicates that a film thickness of a peripheral surface of the substrate is greater than that of a central surface thereof, an exposure amount of a main component of a process gas per unit area of the substrate on the peripheral surface is set to be smaller than that on the central surface.

### (Supplementary Note 6)

In the method according to any one of Supplementary Notes 1 to 5, preferably, when a film thickness distribution of the first silicon-containing layer indicates that a film thickness of a peripheral surface of the substrate is greater than that of a central surface thereof, an amount of a process gas supplied to the peripheral surface is set to be smaller than that of the central surface.

### (Supplementary Note 7)

In the method according to any one of Supplementary Notes 1 to 6, preferably, when a film thickness distribution of the first silicon-containing layer indicates that a film thickness of a peripheral surface of the substrate is greater than that of a central surface thereof, a concentration of a main component of a process gas supplied to the peripheral surface is set to be smaller than that of the central surface.

### (Supplementary Note 8)

In the method according to Supplementary Note 7, preferably, a supply amount of an inert gas added to the process gas supplied to the peripheral surface is set to be greater than that of an inert gas added to the process gas supplied to the central surface in controlling the concentration of the process gas.

### (Supplementary Note 9)

In the method according to any one of Supplementary Notes 1 to 8, preferably, when a film thickness distribution of the first silicon-containing layer indicates that a film thickness of a peripheral surface of the substrate is greater than that of a central surface thereof, in the act of forming a second silicon-containing layer, a temperature of the central surface of the substrate is set to be higher than that of the peripheral surface.

### (Supplementary Note 10)

In the method according to any one of Supplementary Notes 1 to 4, preferably, when a film thickness distribution of the first silicon-containing layer indicates that a film thickness of a peripheral surface of the substrate is smaller than that of a central surface thereof, in the act of forming a second silicon-containing layer, an exposure amount of a main component of a process gas per unit area of the substrate on the peripheral surface is set to be greater than that on the central surface.

### (Supplementary Note 11)

In the method according to any one of Supplementary Notes 1 to 4, or 10, preferably, when a film thickness distribution of the first silicon-containing layer indicates that a film thickness of a peripheral surface of the substrate is smaller than that of a central surface thereof, in the act of forming a second silicon-containing layer, an exposure amount of a main component of a process gas per unit area of the substrate on the peripheral surface is set to be greater than that on the central surface.

### (Supplementary Note 12)

In the method according to any one of Supplementary Notes 1 to 4, or 10 and 11, preferably, when a film thickness distribution of the first silicon-containing layer indicates that a film thickness of a peripheral surface of the substrate is smaller than that of a central surface thereof, in the act of forming a second silicon-containing layer, an amount of a process gas supplied to the peripheral surface is set to be greater than that of the central surface.

### (Supplementary Note 13)

In the method according to any one of Supplementary Notes 1 to 4, or 10 and 11, preferably, when a film thickness distribution of the first silicon-containing layer indicates that a film thickness of a peripheral surface of the substrate is smaller than that of a central surface thereof, in the act of forming a second silicon-containing layer, a concentration of a main component of a process gas supplied to the peripheral surface is set to be greater than that of the central surface.

### (Supplementary Note 14)

In the method according to Supplementary Note 13, preferably, a supply amount of an inert gas added to the process gas supplied to the central surface is set to be greater than that of an inert gas added to the process gas supplied to the peripheral surface in controlling the concentration of the process gas.

### (Supplementary Note 15)

In the method according to any one of Supplementary Notes 1 to 4, or 11 to 14, preferably, a temperature of the peripheral surface of the substrate is set to be higher than that of the central surface.

### (Supplementary Note 16)

According to another aspect of the present disclosure, there is provided a substrate processing system, including: a first apparatus configured to form an insulating film on a channel region and a first silicon-containing layer on the insulating film as a portion of a silicon-containing film; a second apparatus configured to polish the first silicon-containing layer; a third apparatus configured to measure a film thickness distribution of the polished first silicon-containing layer; and a fourth apparatus configured to form a second silicon-containing layer as a portion of the silicon-containing film on the first silicon-containing layer after being polished to have a film thickness distribution different from the film thickness distribution, thereby correcting a film thickness of the silicon-containing film.

### (Supplementary Note 17)

According to still another aspect of the present disclosure, there is provided a substrate processing apparatus, including: a reception part configured to receive film thickness distribution data of a substrate on which a channel region, an insulating film formed on the channel region and a first silicon-containing layer as a portion of a silicon-containing film on the insulating film are formed; a substrate mounting part configured to mount the substrate; and a gas supply part configured to supply a gas to form a second silicon-containing layer as a portion of the silicon-containing film on the first silicon-containing layer to have a film thickness distribution different from a film thickness distribution of the film thickness distribution data, thereby correcting a film thickness of the silicon-containing film.

### (Supplementary Note 18)

According to still another aspect of the present disclosure, there is provided a method of manufacturing a substrate device, including: receiving film thickness distribution data of a substrate on which a channel region, an insulating film formed on the channel region and a first silicon-containing layer as a portion of a silicon-containing film on the insulating film are formed; mounting the substrate on a substrate mounting part; and forming a second silicon-containing layer as a portion of the silicon-containing film on the first silicon-containing layer to have a film thickness distribution different from a film thickness distribution of the film thickness distribution data based on the film thickness distribution data, thereby correcting a film thickness of the silicon-containing film.

### (Supplementary Note 19)

According to still another aspect of the present disclosure, there is provided a program that causes a computer to perform a process of: receiving film thickness distribution data of a substrate on which a channel region, an insulating film formed on the channel region, and a first silicon-containing layer as a portion of a silicon-containing film on the insulating film are formed; mounting the substrate on a substrate mounting part; and forming a second silicon-containing layer as a portion of the silicon-containing film on the first silicon-containing layer to have a film thickness distribution different from a film thickness distribution of the film thickness distribution data based on the film thickness distribution data, thereby correcting a film thickness of the silicon-containing film.

### (Supplementary Note 20)

According to still another aspect of the present disclosure, there is provided a non-transitory computer-readable recording medium storing a program that causes a computer to perform a process of: receiving film thickness distribution data of a substrate on which a channel region, an insulating film on the channel region, and a first silicon-containing layer as a portion of a silicon-containing film on the insulating film are formed; mounting the substrate on a substrate mounting part; and forming a second silicon-containing layer as a portion of the silicon-containing film on the first silicon-containing layer to have a film thickness distribution different from a film thickness distribution of the film thickness distribution data based on the film thickness distribution data, thereby correcting a film thickness of the silicon-containing film.

### (Supplementary Note 21)

According to still another aspect of the present disclosure, there is provided a program that causes a computer to perform a process of: forming an insulating film on a channel region formed on a substrate; forming a first silicon-containing layer as a portion of a silicon-containing film on the insulating film; polishing the substrate; measuring a film thickness distribution of the first silicon-containing film in-plane above the surface of the substrate; and forming a second silicon-containing layer as a portion of the silicon-containing film on the first silicon-containing layer after being polished to have a film thickness distribution different from the film thickness distribution, thereby correcting a film thickness of the silicon-containing film.

### (Supplementary Note 22)

According to still another aspect of the present disclosure, there is provided a non-transitory computer-readable recording medium storing a program that causes a computer to perform a process of: forming an insulating film on a channel region formed on a substrate; forming a first silicon-containing layer as a portion of a silicon-containing film on the insulating film; polishing the substrate; measuring a film thickness distribution of the first silicon-containing film in-plane above the surface of the substrate; and forming a second silicon-containing layer as a portion of the silicon-containing film on the first silicon-containing layer after being polished to have a film thickness distribution different from the film thickness distribution, thereby correcting a film thickness of the silicon-containing film.

According to the present disclosure in some embodiments, it is possible to suppress variation in characteristics of a semiconductor device.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, comprising:
generating film thickness distribution data of a substrate on which a channel region, an insulating film on the channel region, and a first silicon-containing layer as a portion of a silicon-containing film on the insulating film are formed, by measuring a film thickness of the substrate;
receiving the film thickness distribution data of the substrate;
mounting the substrate on a substrate mounting part; and
forming a second silicon-containing layer as a portion of the silicon-containing film on the first silicon-containing layer to have a film thickness distribution different from a film thickness distribution of the film thickness distribution data to thereby correct a film thickness of the silicon-containing film.

2. The method of claim 1, wherein forming the second silicon-containing layer includes setting an exposure amount of a main component of a process gas per unit area of the substrate on a peripheral surface of the substrate smaller than that on a central surface thereof when a film thickness distribution of the first silicon-containing layer in the film thickness distribution data indicates that a film thickness of the peripheral surface of the substrate is greater than that of the central surface thereof.

3. The method of claim 2, wherein forming the second silicon-containing layer further includes setting a temperature of the central surface of the substrate higher than that of the peripheral surface thereof when the film thickness distribution of the first silicon-containing layer in the film thickness distribution data indicates that the film thickness of the peripheral surface of the substrate is greater than that of the central surface thereof.

4. The method of claim 1, wherein forming the second silicon-containing layer includes setting an amount of a process gas supplied to a peripheral surface of the substrate smaller than that supplied to a central surface thereof when a film thickness distribution of the first silicon-containing layer in the film thickness distribution data indicates that a film thickness of the peripheral surface of the substrate is greater than that of the central surface thereof.

5. The method of claim 4, wherein forming the second silicon-containing layer further includes setting a temperature of the central surface of the substrate higher than that of the peripheral surface thereof when the film thickness distribution of the first silicon-containing layer in the film thickness distribution data indicates that the film thickness of the peripheral surface of the substrate is greater than that of the central surface thereof.

6. The method of claim 1, wherein forming the second silicon-containing layer includes setting a concentration of a main component of a process gas supplied to a peripheral surface of the substrate smaller than that supplied to a central surface thereof when a film thickness distribution of the first silicon-containing layer in the film thickness distribution data indicates that a film thickness of the peripheral surface of the substrate is greater than that of the central surface thereof.

7. The method of claim 6, wherein setting the concentration of the main component of the process gas includes setting a supply amount of an inert gas added to the process gas supplied to the peripheral surface greater than a supply amount of an inert gas added to the process gas supplied to the central surface.

8. The method of claim 1, wherein forming the second silicon-containing layer includes setting a temperature of a central surface of the substrate higher than that of a peripheral surface thereof when a film thickness distribution of the first silicon-containing layer in the film thickness distribution data indicates that a film thickness of the peripheral surface of the substrate is greater than that of the central surface thereof.

9. The method of claim 1, wherein forming the second silicon-containing layer includes setting an exposure amount of a main component of a process gas per unit area of the substrate on a peripheral surface of the substrate greater than that on a central surface thereof when a film thickness distribution of the first silicon-containing layer in the film thickness distribution data indicates that a film thickness of the peripheral surface of the substrate is smaller than that of the central surface thereof.

10. The method of claim 9, wherein forming the second silicon-containing layer further includes setting a temperature of the peripheral surface of the substrate higher than that of the central surface when the film thickness distribution of the first silicon-containing layer in the film thickness distribution data indicates that the film thickness of the peripheral surface of the substrate is smaller than that of the central surface thereof.

11. The method of claim 1, wherein forming the second silicon-containing layer includes setting an amount of a process gas supplied to a peripheral surface of the substrate greater than that supplied to a central surface thereof when a film thickness distribution of the first silicon-containing layer in the film thickness distribution data indicates that a film thickness of the peripheral surface of the substrate is smaller than that of the central surface thereof.

12. The method of claim 11, wherein forming the second silicon-containing layer further includes setting a temperature of the peripheral surface of the substrate higher than that of the central surface thereof when the film thickness distribution of the first silicon-containing layer in the film thickness distribution data indicates that the film thickness of the peripheral surface of the substrate is smaller than that of the central surface thereof.

13. The method of claim 1, wherein forming the second silicon-containing layer includes setting a concentration of a main component of a process gas supplied to a peripheral surface of the substrate greater than that supplied to a central surface thereof when a film thickness distribution of the first silicon-containing layer in the film thickness distribution data indicates that a film thickness of the peripheral surface of the substrate is smaller than that of the central surface thereof.

14. The method of claim 13, wherein setting the concentration of the main component of the process gas includes setting a supply amount of an inert gas added to the process gas supplied to the central surface greater than a supply amount of an inert gas added to the process gas supplied to the peripheral surface.

15. The method of claim 1, wherein forming the second silicon-containing layer includes setting a temperature of a peripheral surface of the substrate higher than that of a central surface thereof when a film thickness distribution of the first silicon-containing layer in the film thickness distribution data indicates that a film thickness of the peripheral surface of the substrate is smaller than that of the central surface thereof.
